(19) United States
(12) Patent Application Publication
(10) Pub. No.: US 2023/0387664 A1
(43) Pub. Date: Nov. 30, 2023

(54) SEMICONDUCTOR LASER ELEMENT

(71) Applicant: Panasonic Holdings Corporation, Osaka (JP)

(72) Inventors: Hiroyuki HAGINO, Osaka (JP); Tsuyoshi Tanaka, Osaka (JP)

(21) Appl. No.: 18/232,265

(22) Filed: Aug. 9, 2023

Related U.S. Application Data
(63) Continuation of application No. PCT/JP22/00950, filed on Jan. 13, 2022.

(30) Foreign Application Priority Data
Feb. 10, 2021 (JP) 2021-019607

(51) Int. Cl. H01S 5/22; H01S 5/223

(52) U.S. Cl. CPC H01S 5/222; H01S 5/2231

(57) ABSTRACT

A semiconductor laser element includes: a substrate having a projection at an upper face thereof; a first semiconductor layer; a light emission layer; a second semiconductor layer; and a low refractive index part having a refractive index lower than that of the first semiconductor layer. The second semiconductor layer has a ridge part for guiding laser light generated in the light emission layer. An angle between a side face of the ridge part and the waveguiding direction is larger than a limit angle defined by an effective refractive index on each of an inner side of the ridge part and an outer side of the ridge part. The low refractive index part is disposed between an active layer of the light emission layer and the projection of the substrate, and on the outer side of the side face at least where the width of the ridge part is small.

### CROSS REFERENCE TO RELATED APPLICATION

This application is a continuation of International Application No. PCT/JP2022/000950 filed on Jan. 13, 2022, entitled “SEMICONDUCTOR LASER ELEMENT”, which claims priority under 35 U.S.C. Section 119 of Japanese Patent Application No. 2021-019607 filed on Feb. 10, 2021, entitled “SEMICONDUCTOR LASER ELEMENT”. The disclosures of the above applications are incorporated herein by reference.

### BACKGROUND OF THE INVENTION

### Field of the Invention

The present invention relates to a semiconductor laser element, and is suitable to be used in, for example, processing and the like of products.

The present application is a commissioned research under “Development of advanced laser processing with intelligence based on high-brightness and high-efficiency laser technologies/Development of new light-source/elemental technologies for advanced processing/Development of GaN-based high-power high-beam quality semiconductor lasers for highly-efficient laser processing” of the New Energy and Industrial Technology Development Organization for the fiscal year 2016, and is a patent application to which Article 17 of the Industrial Technology Enhancement Act is applied.

### Description of Related Art

In recent years, semiconductor laser elements have been used in processing of various products. In such a semiconductor laser element, in order to enhance the processing quality, it is preferable that light emitted from the semiconductor laser element has a high output power and the proportion of a fundamental mode is increased, with a higher order mode cut as much as possible.

Japanese Laid-Open Patent Publication No. H9-246664 describes a semiconductor laser element including: a rough surface light waveguide mechanism provided at both side walls of a stripe-shaped ridge part at a center in the waveguiding direction; and a parallel smooth surface light waveguide mechanism provided at both ends in the waveguiding direction. Due to the rough surface light waveguide mechanism, loss in the higher order mode is caused, and the proportion of the fundamental mode is increased.

However, in the configuration described in Japanese Laid-Open Patent Publication No. H9-246664, ripples (disturbance) may be caused in a vertical FFP (Far-Field Pattern). In this case, the shape of emission light is significantly shifted from an ideal Gaussian shape. This causes a problem that the quality of laser light emitted from the semiconductor laser element decreases.

### SUMMARY OF THE INVENTION

A major aspect of the present invention relates to a semiconductor laser element. A semiconductor laser element according to the present aspect includes: a substrate having a projection at an upper face thereof; a first semiconductor layer disposed above the substrate; a light emission layer disposed above the first semiconductor layer; a second semiconductor layer disposed above the light emission layer; and a low refractive index part having a refractive index lower than that of the first semiconductor layer. The second semiconductor layer has a ridge part for guiding laser light generated in the light emission layer. A width of the ridge part cyclically changes in accordance with a position in a waveguiding direction of the ridge part. An angle between a side face of the ridge part and the waveguiding direction is larger than a limit angle defined by an effective refractive index on each of an inner side of the ridge part and an outer side of the ridge part. The low refractive index part is disposed between an active layer of the light emission layer and the projection of the substrate, and on the outer side of the side face at least where the width of the ridge part is small.

According to the semiconductor laser element of the present aspect, since the angle between the side face of the ridge part and the waveguiding direction is set to be larger than the limit angle, laser light in the higher order mode is cut, and the proportion of laser light in the fundamental mode is increased. The low refractive index part is disposed between the active layer of the light emission layer and the projection of the substrate, and on the outer side of the side face at least where the width of the ridge part is small. Accordingly, downward movement of the distribution position of laser light propagating at the ridge part (waveguide) is less likely to occur, and thus, ripples in the vertical FFP is suppressed. When the projection is provided at the upper face of the substrate, a portion near the lower end of laser light in the fundamental mode propagating in the ridge part can be suppressed from being radiated from the upper face of the substrate where the projection is not disposed. Accordingly, decrease in laser light in the fundamental mode can be suppressed. Thus, while ripples in the vertical FFP are suppressed, the proportion of the fundamental mode can be increased.

The effects and the significance of the present invention will be further clarified by the description of the embodiment below. However, the embodiment below is merely an example for implementing the present invention. The present invention is not limited to the embodiment below in any way.

### BRIEF DESCRIPTION OF THE DRAWINGS

FIG. 1 is a top view schematically showing a configuration of a semiconductor laser element according to an embodiment.

FIG. 2 is a cross-sectional view schematically showing a configuration of the semiconductor laser element at an A-A′ cross section viewed in the Y-axis positive direction, according to the embodiment.

FIGS. 3A and 3B are each a cross-sectional view for describing a production method for the semiconductor laser element, according to the embodiment.

FIGS. 4A and 4B are each a cross-sectional view for describing a production method for the semiconductor laser element, according to the embodiment.

FIGS. 5A and 5B are each a cross-sectional view for describing a production method for the semiconductor laser element, according to the embodiment.

FIGS. 6A and 6B are each a cross-sectional view for describing a production method for the semiconductor laser element, according to the embodiment.

FIGS. 7A and 7B are each a cross-sectional view for describing a production method for the semiconductor laser element, according to the embodiment.

FIGS. 8A and 8B are each a cross-sectional view for describing a production method for the semiconductor laser element, according to the embodiment.

FIGS. 9A and 9B are each a cross-sectional view for describing a production method for the semiconductor laser element, according to the embodiment.

FIGS. 10A and 10B are each a cross-sectional view for describing a production method for the semiconductor laser element, according to the embodiment.

FIG. 11 is a cross-sectional view schematically showing a configuration of a semiconductor laser device according to the embodiment.

FIG. 12 is a top view schematically showing sizes of a side face of a ridge part, according to the embodiment.

FIG. 13A is a graph showing a relationship between a refractive index difference between the inside and the outside of the ridge part, and a limit angle, according to the embodiment.

FIG. 13B is a graph showing a relationship between a given distance of the side face in the Y-axis direction and the local minimum value of the width of the side face in the X-axis direction, according to the embodiment.

FIG. 14A is a top view schematically showing a configuration of a semiconductor laser element according to Comparative Example 1. FIGS. 14B and 14C are cross-sectional views, respectively, schematically showing configurations of a semiconductor laser at an A11-Al2 cross section and an A21-A22 cross section viewed in the Y-axis positive direction, according to Comparative Example 1.

FIG. 15 is a top view schematically showing a configuration of a semiconductor laser element according to Comparative Example 2.

FIG. 16 is graphs showing a result of an experiment on vertical FFP obtained when the structures of ridge parts of the semiconductor laser elements according to Comparative Examples 1 and 2 are changed.

FIG. 17A is a top view schematically showing a configuration of the semiconductor laser element according to the embodiment. FIGS. 17B and 17C are cross-sectional views, respectively, schematically showing configurations of a semiconductor laser at an A31-A32 cross section and an A41-A42 cross section viewed in the Y-axis positive direction, according to the embodiment.

FIG. 18A is a cross-sectional view schematically showing a configuration of a semiconductor laser element according to Modification 1. FIG. 18B is a cross-sectional view schematically showing a configuration of a semiconductor laser element according to Modification 2.

FIG. 19 is a cross-sectional view schematically showing a configuration of a semiconductor laser element according to Modification 3.

FIG. 20 is a cross-sectional view schematically showing a configuration of a semiconductor laser element according to Modification 4.

FIG. 21 is a top view schematically showing a configuration of a semiconductor laser element according to Modification 5.

FIG. 22 is a top view schematically showing a configuration of a semiconductor laser element according to Modification 6.

It should be noted that the drawings are solely for description and do not limit the scope of the present invention by any degree.

### DETAILED DESCRIPTION

Hereinafter, an embodiment of the present invention will be described with reference to the drawings. For convenience, each drawing is provided with, X, Y, and Z axes orthogonal to each other. The X-axis direction is the width direction of a ridge part, and the Y-axis direction is the propagation direction (resonator longitudinal direction) of light at the ridge part. The Z-axis direction is the lamination direction of layers forming a semiconductor laser element, and the Z-axis positive direction is the upward direction.

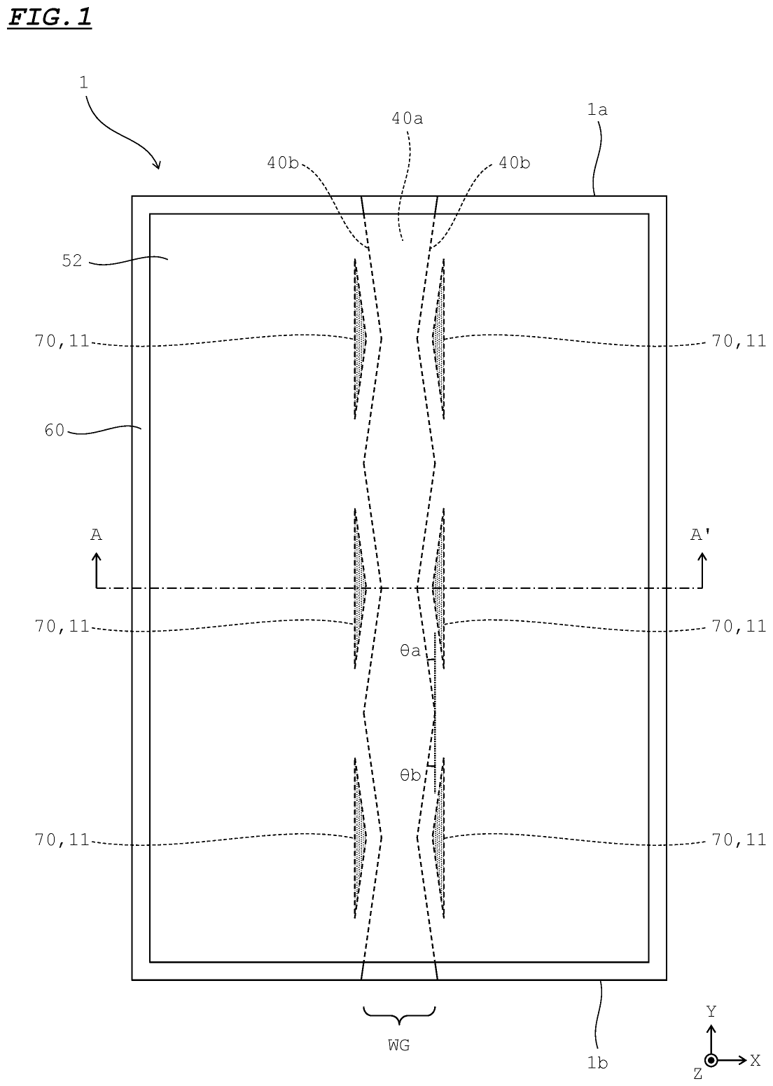

FIG. 1 is a top view schematically showing a configuration of a semiconductor laser element 1.

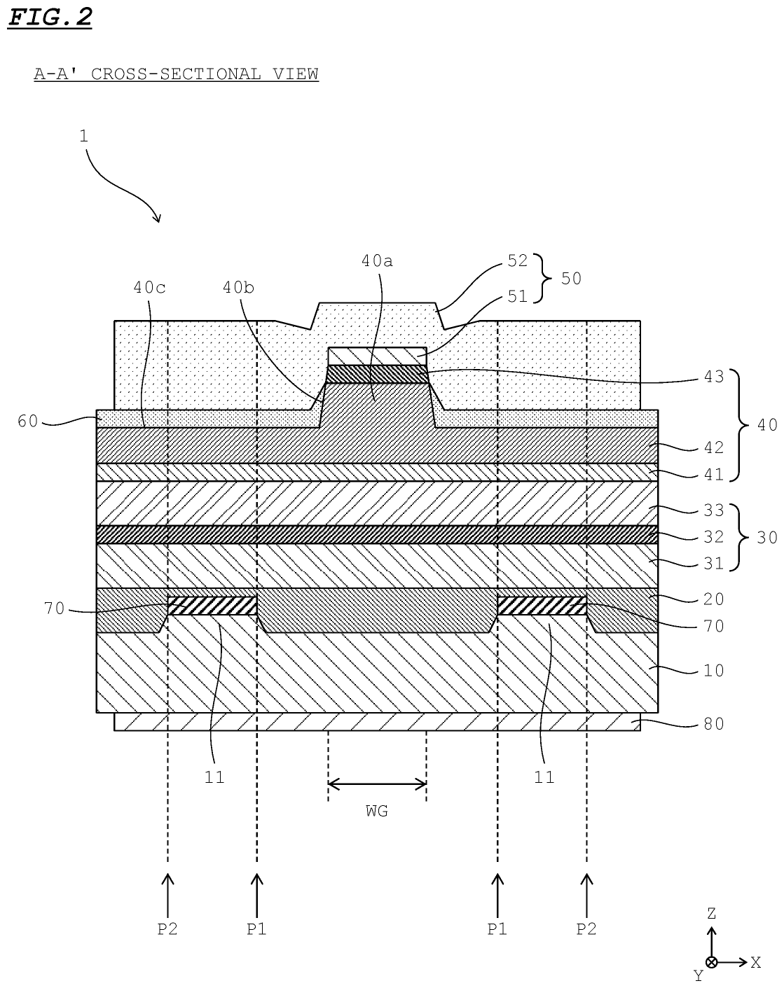

In the semiconductor laser element 1, a ridge part 40a linearly extending in the Y-axis direction is provided in the vicinity of the center in the X-axis direction. The ridge part forms a waveguide WG that guides laser light. The ridge part propagates, along the ridge part 40a, laser light that is generated in a light emission layer 30 (see FIG. 2) and that oscillates in the semiconductor laser element 1. A side face 40b is provided at each of ends on the X-axis positive side and the X-axis negative side of the ridge part 40a. In a top view, the side face 40b forms an angle θa or an angle θb with respect to a Y-Z plane, whereby the width of the ridge part 40a cyclically changes in accordance with the waveguiding direction (the Y-axis direction) of the ridge part 40a.

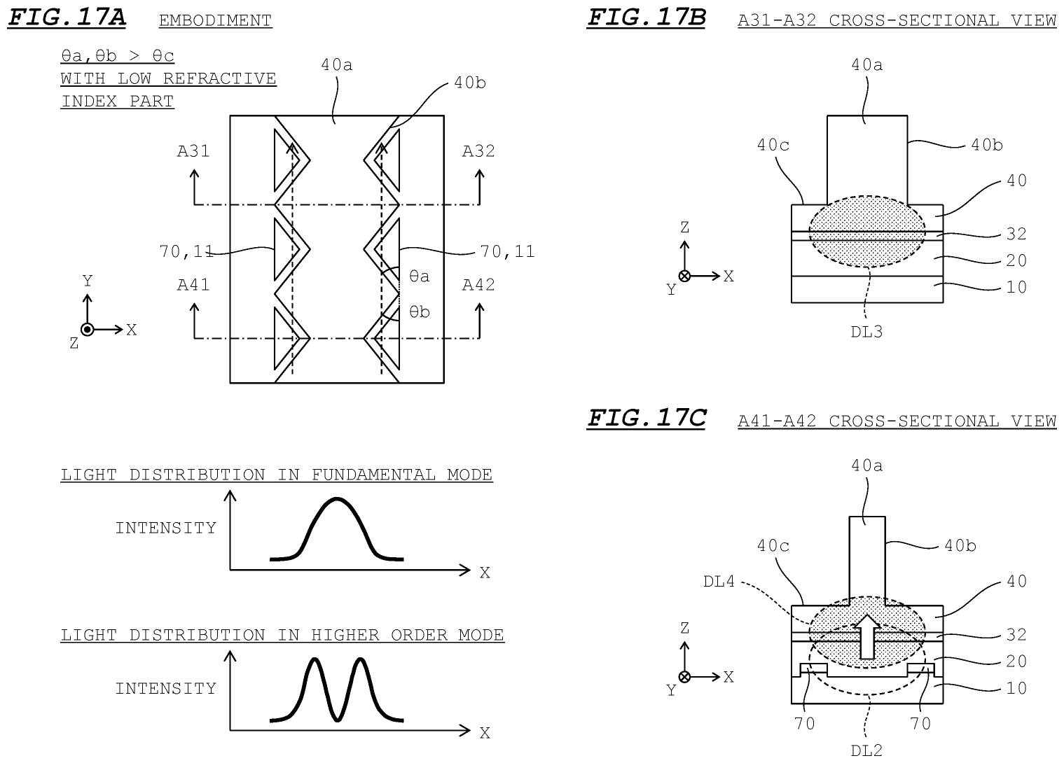

On each outer side of each portion where the width in the X-axis direction of the ridge part 40a is small, a low refractive index part 70 and a projection 11 of a substrate 10 (see FIG. 2) are provided. The low refractive index part 70 and the projection 11 each have a triangular shape in a top view, and the width in the X-axis direction of the low refractive index part 70 and the projection 11 is different in accordance with the position in the Y-axis direction. At a position in the Y-axis direction where the width in the X-axis direction of the ridge part 40a becomes small, the width in the X-axis direction of the low refractive index part 70 and the projection 11 becomes large. The position in the Z-axis direction of the low refractive index part 70 and the projection 11 will be described with reference to FIG. 2 later. Effects due to the low refractive index part 70 and the projection 11 will be described with reference to FIGS. 17A to 17C later.

An end face 1a is the end face of the ridge part 40a positioned on the Y-axis positive side, and is the end face on the emission side of the semiconductor laser element 1. An end face 1b is the end face of the ridge part 40a positioned on the Y-axis negative side, and is the end face on the reflection side of the semiconductor laser element 1. An end face coat film is formed at each of the end faces 1a, 1b. When light (forward wave) advancing from the end face 1b side toward the end face 1a side has reached the end face 1a, a part of the forward wave is emitted as emission light from the end face 1a in the Y-axis positive direction, and a part of the forward wave is reflected at the end face 1a to be light (backward wave) advancing from the end face 1a side toward the end face 1b. When the backward wave advances through the ridge part 40a in the Y-axis negative direction and reaches the end face 1b, most of the backward wave is reflected at the end face 1b to be a forward wave. In this manner, the light generated in the semiconductor laser element 1 is amplified between the end face 1a and the end face 1b, to be emitted from the end face 1a.

FIG. 2 is a cross-sectional view schematically showing a configuration of the semiconductor laser element 1 shown in FIG. 1 at an A-A′ cross section viewed in the Y-axis positive direction.

As shown in FIG. 2, the semiconductor laser element 1 includes the substrate 10, a first semiconductor layer 20, the light emission layer 30, a second semiconductor layer 40, an electrode member 50, a dielectric layer 60, the low refractive index part 70, and an n-side electrode 80.

The substrate 10 has the projection 11 at the upper face thereof. The projection 11 projects in the upward direction with respect to the upper face of the substrate 10. The projection 11 is formed on the outer side of the ridge part 40a in the X-axis direction.

The first semiconductor layer 20 is disposed above the substrate 10. The first semiconductor layer 20 is an n-side clad layer.

The light emission layer 30 is disposed above the first semiconductor layer 20. The light emission layer 30 has a laminated structure in which an n-side light guide layer 31, an active layer 32, and a p-side light guide layer 33 are laminated from the bottom in this order. When a voltage is applied to the semiconductor laser element 1, light is generated and propagates in the light emission layer 30.

The second semiconductor layer 40 is disposed above the light emission layer 30. The second semiconductor layer 40 has a laminated structure in which an electron barrier layer 41, a A-side clad layer 42, and a p-side contact layer 43 are laminated from the bottom in this order.

In an upper portion of the second semiconductor layer 40, the ridge part 40a is formed in the vicinity of the center in the X-axis direction. The ridge part 40a has a shape projecting in the Z-axis positive direction, and has a ridge shape (protrusion shape) extending in the Y-axis direction. Since the ridge part 40a is formed, the waveguide WG is formed so as to correspond to the range in the X-axis direction of the ridge part 40a. Since the ridge part 40a is formed, the side face 40b is formed at each of the end on the X-axis positive side and the end on the X-axis negative side of the ridge part 40a. In an upper portion of the second semiconductor layer 40, a flat part 40c extending in the X-axis direction from the root of the ridge part 40a is formed.

The electrode member 50 is disposed above the second semiconductor layer 40. The electrode member 50 includes a p-side electrode 51 for applying a voltage, and a pad electrode 52 disposed above the p-side electrode 51. The p-side electrode 51 is disposed at the upper face of the ridge part 40a. The p-side electrode 51 is an ohmic electrode that is in ohmic contact with the p-side contact layer 43 above the p-side contact layer 43. The pad electrode 52 has a shape longer in the X-axis direction than the ridge part 40a, and is in contact with the p-side electrode 51 and the dielectric layer 60.

The dielectric layer 60 is disposed above the p-side clad layer 42 on the outer side in the X-axis direction of the ridge part 40a, in order to confine light in the ridge part 40a. Specifically, the dielectric layer 60 is continuously formed from the side face 40b over the flat part 40c. The dielectric layer 60 is implemented by an insulation film having a refractive index lower than that of the ridge part 40a.

The low refractive index part 70 is disposed in the first semiconductor layer 20 in the Z-axis direction, and is disposed on the outer side of the ridge part 40a in the X-axis direction and on the projection 11 of the substrate 10. The low refractive index part 70 is formed of a material having a refractive index lower than that of the first semiconductor layer 20, the light emission layer 30, and the second semiconductor layer 40. In the present embodiment, the low refractive index part 70 is formed of a dielectric material composed of a silicon oxide film. With the low refractive index part 70, occurrence of ripples (disturbance) in the vertical FFP can be suppressed, as described later with reference to FIGS. 17A to 17C. In the present embodiment, since the cross section of the low refractive index part 70 has a rectangular shape, the inner end and the outer end in the X-axis direction of the low refractive index part 70 become parallel to the Z-axis direction. Accordingly, in the vicinity of a position P1 at the inner end and in the vicinity of a position P2 at the outer end, an interface is caused at each layer as indicated by a broken line, and laser light in a higher order mode is scattered by this interface.

The n-side electrode 80 is disposed below the substrate and is an ohmic electrode in ohmic contact with the substrate 10.

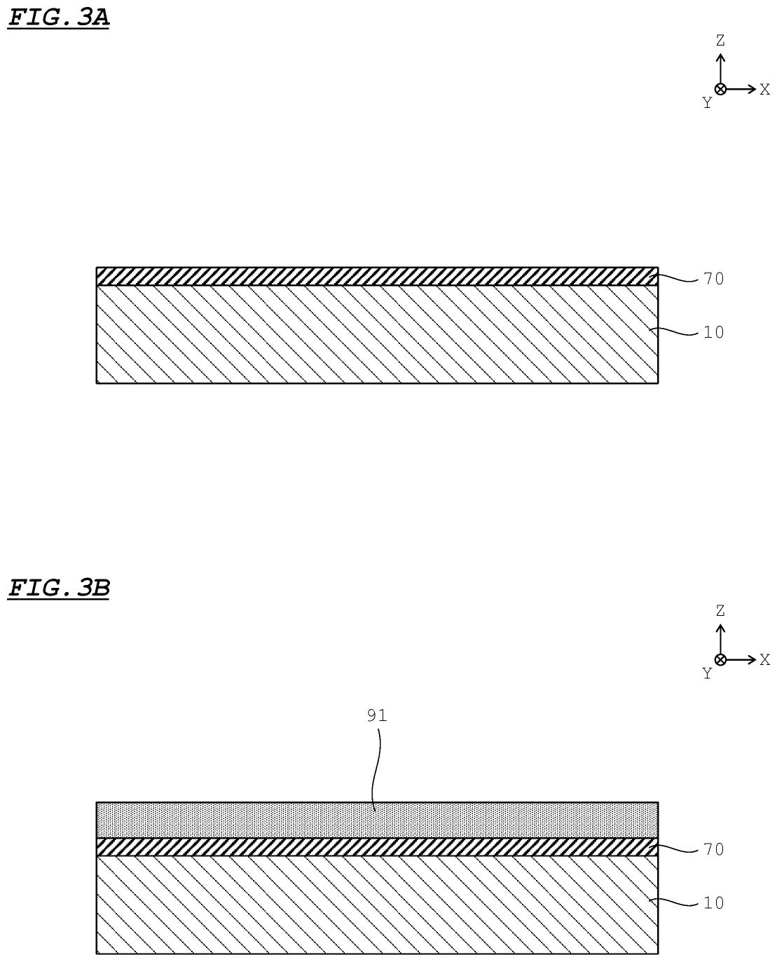

Next, with reference to FIG. 3A to FIG. 10B, a production method for the semiconductor laser element 1 will be described. FIG. 3A to FIG. 10B are cross-sectional views similar to that in FIG. 2.

Hereinafter, in growth of each layer, as organometal raw materials including Ga, Al, and In, trimethylgallium (TMG), trimethyl ammonium (TMA), and trimethylindium (TMI) are respectively used, for example. As a nitrogen raw material, ammonia (NH₃) is used. As a lithography method, a photolithography method using a short wavelength light source, an electron beam lithography method in which rendering is directly performed by an electron beam, a nanoimprint method, or the like can be used. As an etching method, for example, dry etching by reactive ion etching (RIE) using a fluorine-based gas such as CF₄, or wet etching using hydrofluoric acid (HF) or the like diluted to about 1:10, can be used.

As shown in FIG. 3A, the low refractive index part 70 is formed on the substrate 10 which is an n-type hexagonal GaN substrate whose main face is a (0001) plane. Specifically, a 100 nm silicon oxide film (SiO₂) is formed as the low refractive index part 70 on the substrate 10 by a plasma CVD (Chemical Vapor Deposition) method using silane (SiH₄). The film formation method for the low refractive index part 70 is not limited to the plasma CVD method, and a known film formation method such as a thermal CVD method, a sputtering method, a vacuum evaporation method, a pulsed laser film formation method, or the like can be used, for example.

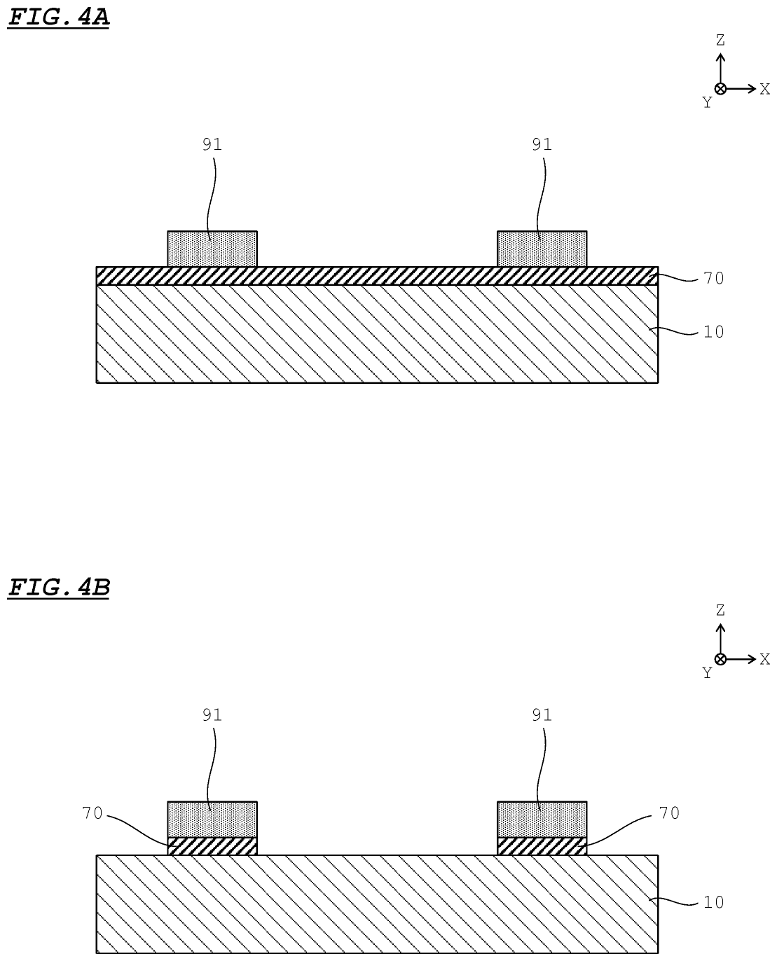

Next, as shown in FIG. 3B, a first protection film 91 composed of a photoresist is formed on the low refractive index part 70. Next, as shown in FIG. 4A, using a photolithography method, patterning is performed such that the first protection film 91 remains only at desired places. That is, the first protection film 91 is selectively removed such that the first protection film 91 remains in a predetermined shape. The predetermined shape is a shape in a top view of the low refractive index part 70 shown in FIG. 1.

Next, as shown in FIG. 4B, using the first protection film 91 as a mask, the low refractive index part 70 is etched.

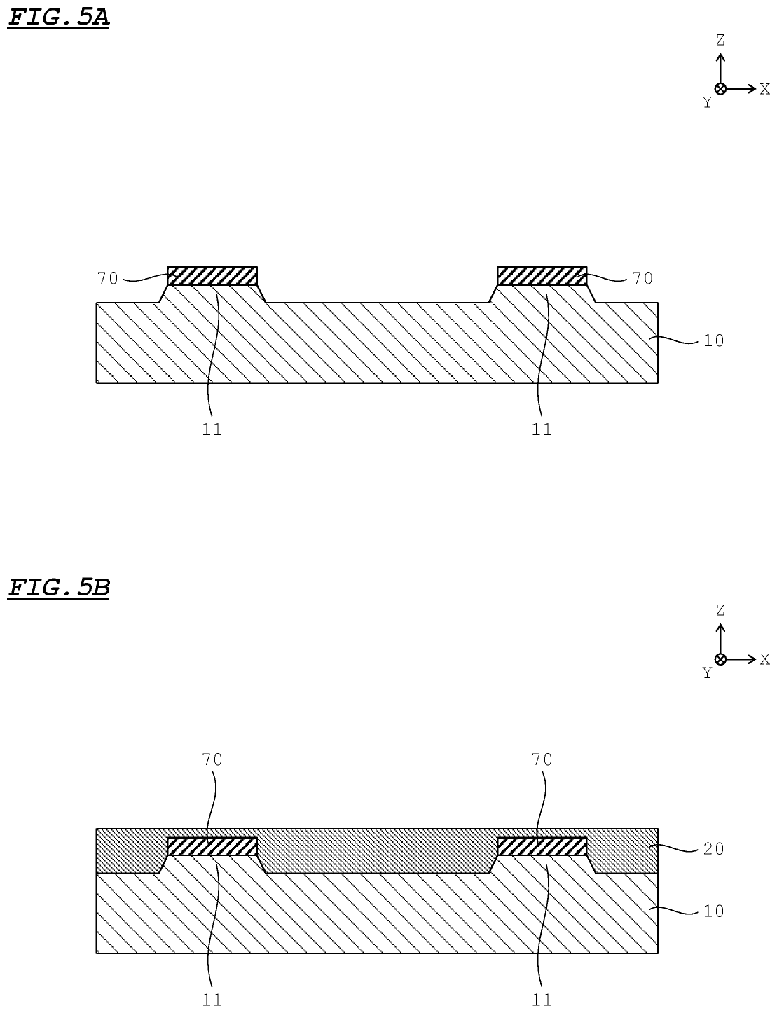

Next, as shown in FIG. 5A, the first protection film 91 is removed. For removal of the first protection film 91, an organic solvent such as acetone can be used.

Further, using the low refractive index part 70 as a mask, the substrate 10 is etched. As the etching, dry etching by an RIE method using a chlorine-based gas such as Cl₂ may be used. Through the etching of the substrate 10, the level of the upper face of the substrate 10 where the low refractive index part 70 is not disposed becomes further lower, and the projection 11 is formed at the lower face of the low refractive index part 70. The height of the projection 11 in the Z-axis direction is not limited in particular, but is not less than 50 nm and not greater than 1 μm. In order to cause the semiconductor laser element 1 to operate at a high light output (e.g., watt class), the height of the projection 11 may be set to not greater than 300 nm. In the present embodiment, the height of the projection 11 is 100 nm.

Next, as shown in FIG. 5B, by a metalorganic chemical vapor deposition (MOCVD method), the first semiconductor layer 20 is formed on the substrate 10 and the low refractive index part 70. Specifically, as the first semiconductor layer 20, an n-side clad layer of an n-type AlGaN is grown by 3 μm. Accordingly, formation of the first semiconductor layer 20 is completed and the low refractive index part 70 is positioned in the first semiconductor layer 20.

Here, the crystal growth state on the low refractive index part 70 can be controlled by a growth condition of the first semiconductor layer 20. For example, when the growth temperature is set to a high temperature, diffusion of the raw material easily occurs, crystal growth in the lateral direction (the X-axis direction) is promoted, and a nitride semiconductor layer can be formed in a relatively flat manner, also on the low refractive index part 70.

When the first semiconductor layer 20 is formed, crystals having grown from the left and the right (the X-axis direction) of the low refractive index part 70 grow so as to cover the low refractive index part 70, and join each other on the low refractive index part 70. Through this joining, an interface is caused at the first semiconductor layer 20 positioned directly above the low refractive index part 70, and defects are introduced at this interface. Accordingly, the defect density of the first semiconductor layer 20 disposed directly above the low refractive index part 70 becomes higher than the defect density of the first semiconductor layer 20 other than directly above the low refractive index part 70.

As described above, when defects are introduced at an interface of the first semiconductor layer 20 positioned directly above the low refractive index part 70, an interface is similarly caused directly above the low refractive index part 70 also at each layer laminated above the first semiconductor layer 20, and defects are introduced at this interface. Accordingly, at each layer above the first semiconductor layer 20, the defect density directly above the low refractive index part 70 becomes higher than the defect density other than directly above the low refractive index part 70. In particular, when defects are introduced at the light emission layer 30 directly above the low refractive index part 70, unnecessary light in the higher order mode distributed in the vicinity of the light emission layer 30 directly above the low refractive index part 70 can be weakened.

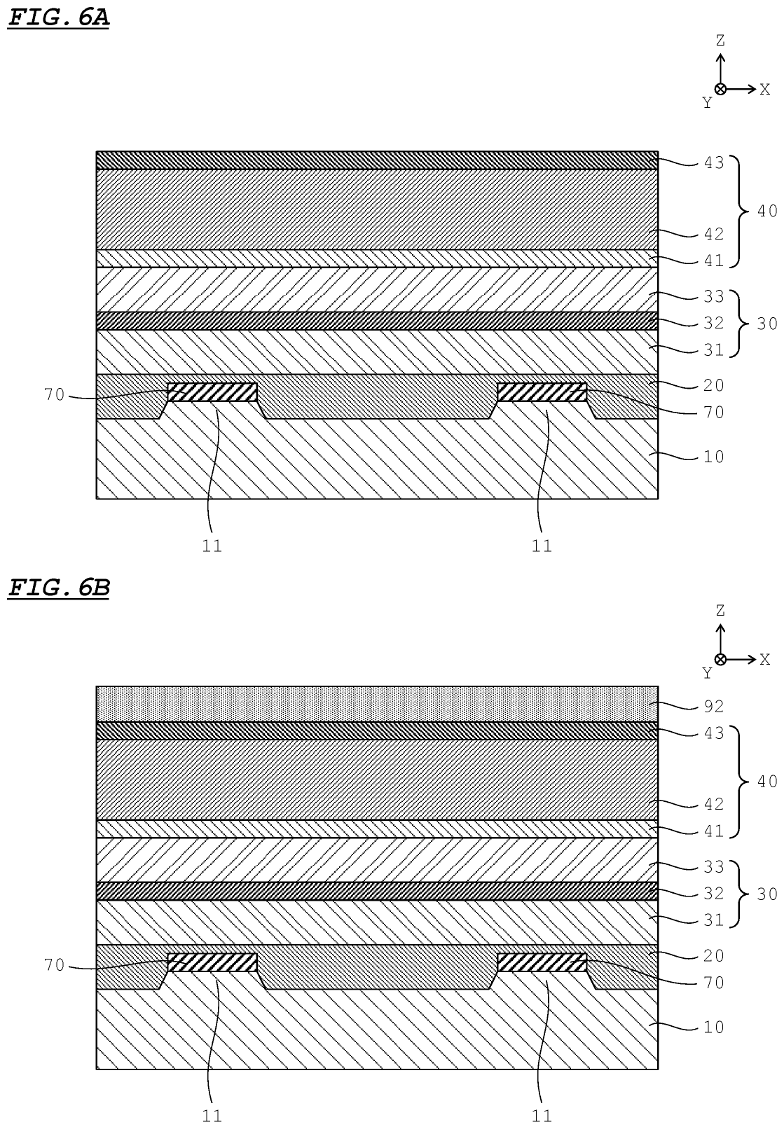

Next, as shown in FIG. 6A, the light emission layer 30 and the second semiconductor layer 40 are sequentially formed on the first semiconductor layer 20, using the metalorganic chemical vapor deposition. Specifically, the n-side light guide layer 31 of an n-type GaN is grown by 0.2 μm. Subsequently, the active layer 32 composed of two cycles of a barrier layer of InGaN and an InGaN quantum well layer is grown. Subsequently, the p-side light guide layer 33 of a p-type GaN is grown by 0.1 μm. Subsequently, the electron barrier layer 41 of AlGaN is grown by 10 nm. Subsequently, the p-side clad layer 42 is grown as a 0.66 μm-thick strained superlattice, by repeating 220 cycles of a 1.5 nm-thick p-type AlGaN layer and a 1.5 nm-thick p-type GaN layer. Subsequently, the p-side contact layer 43 of a p-type GaN is grown by 0.05 μm.

Next, as shown in FIG. 6B, a second protection film 92 is formed on the second semiconductor layer 40. Specifically, a 300 nm silicon oxide film (SiO₂) is formed as the second protection film 92 on the second semiconductor layer 40 by a plasma CVD method using silane (SiH₄). The film formation material of the second protection film 92 is not limited to the above, and, for example, a material, such as a dielectric or a metal, that is selective with respect to etching of the second semiconductor layer 40 described later may be used.

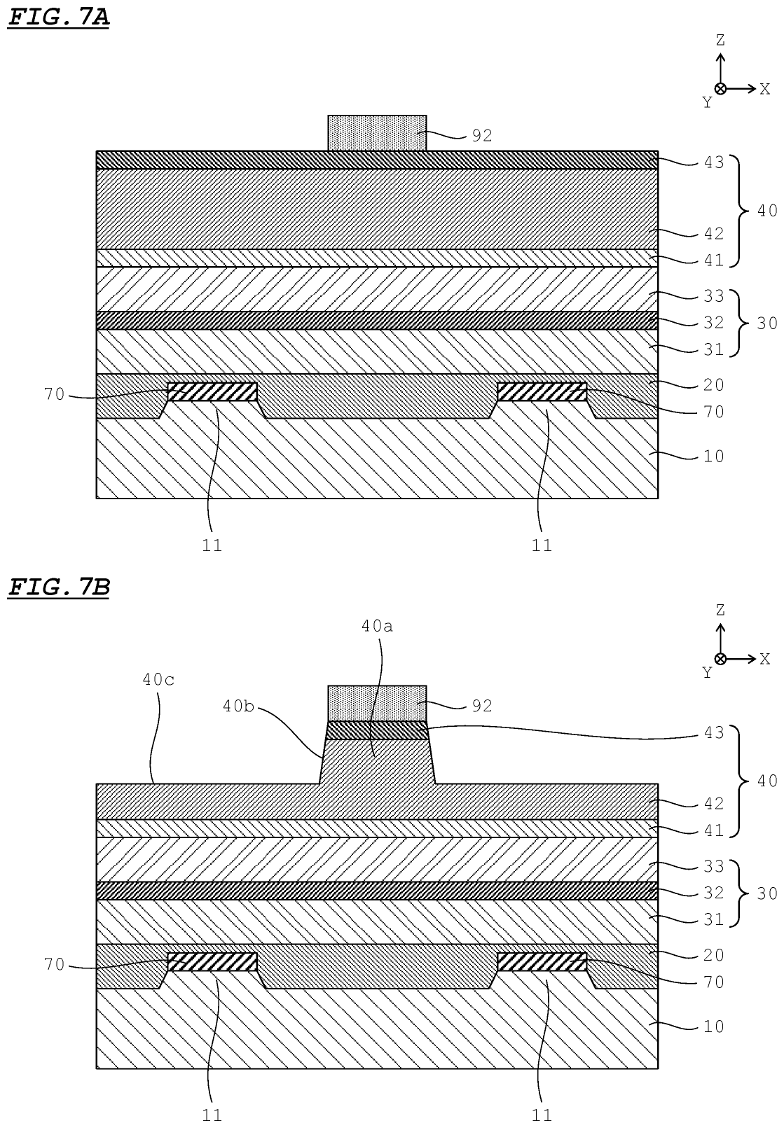

Next, as shown in FIG. 7A, the second protection film 92 is selectively removed by using a photolithography method and an etching method such that the second protection film 92 remains in a predetermined shape. The predetermined shape is a shape in a top view of the ridge part 40a shown in FIG. 1. That is, the predetermined shape is a belt-like shape whose width, in a top view, changes with respect to the position in the Y-axis direction (the resonator longitudinal direction).

Next, as shown in FIG. 7B, the p-side contact layer 43 and the p-side clad layer 42 are etched by using, as a mask, the second protection film 92 formed in the predetermined shape, whereby the ridge part 40a and the flat part 40c are formed in the second semiconductor layer 40.

Specifically, the ridge part 40a is formed below the second protection film 92 positioned at the center in the X-axis direction. The ridge part 40a is composed of a projection of the p-side clad layer 42 projecting in the Z-axis positive direction, and the p-side contact layer 43 on this projection. The p-side contact layer 43 and the p-side clad layer 42 in the region where the second protection film 92 is not formed are etched, whereby the flat part 40c is formed. For etching of the p-side contact layer 43 and the p-side clad layer 42, dry etching by an RIE method using a chlorine-based gas such as Cl₂ may be used.

The height of the ridge part 40a in the Z-axis direction is not limited in particular, but as an example, is not less than 100 nm and not greater than 1 μm. In order to cause the semiconductor laser element 1 to operate at a high light output (e.g., watt class), the height of the ridge part 40a may be set to not less than 300 nm and not greater than 800 nm. In the present embodiment, the height of the ridge part 40a is 650 nm.

The ridge part 40a is formed using, as a mask, the second protection film 92 formed in the predetermined shape. Therefore, as shown in the top view in FIG. 1, the side faces 40b of the ridge part 40a form a belt-like shape whose width in the X-axis direction changes with respect to the position in the Y-axis direction (the resonator longitudinal direction).

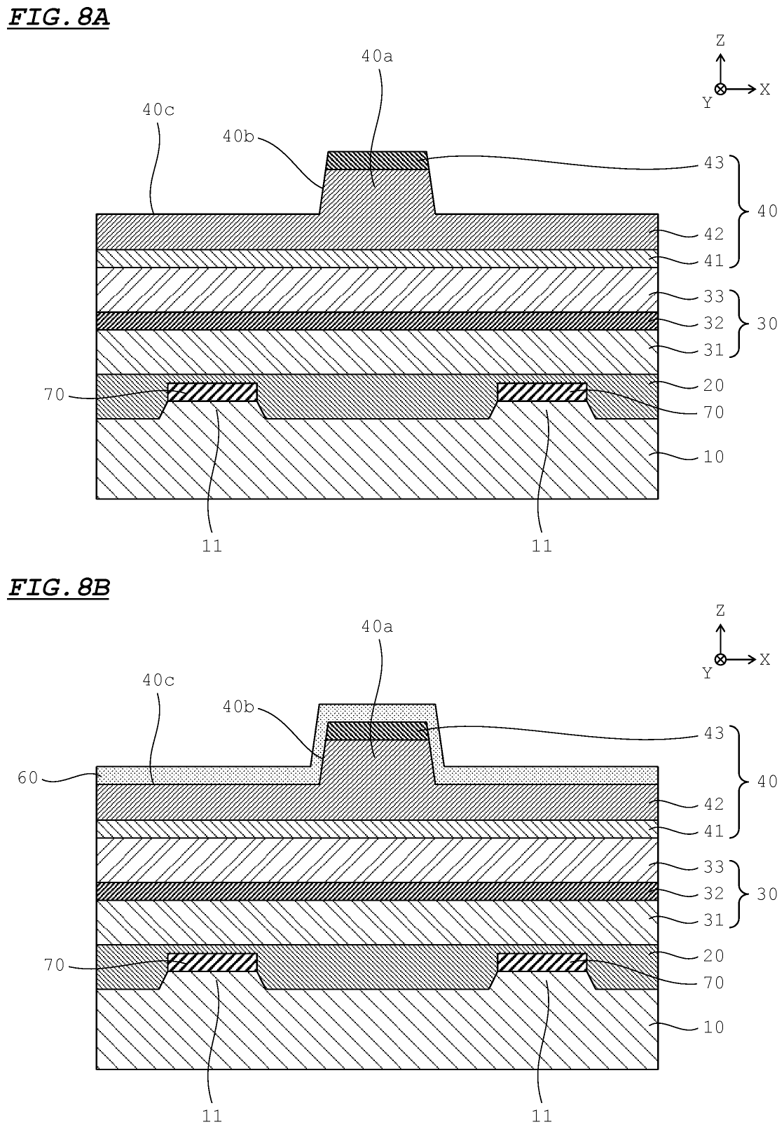

Next, as shown in FIG. 8A, the second protection film 92 is removed by wet etching using hydrofluoric acid or the like.

Next, as shown in FIG. 8B, the dielectric layer 60 is formed so as to cover the p-side contact layer 43 and the p-side clad layer 42. Accordingly, the dielectric layer 60 is formed on the ridge part 40a and the flat part 40c. As the dielectric layer 60, a 300 nm silicon oxide film (SiO₂) is formed by a plasma CVD method using silane (SiH₄), for example.

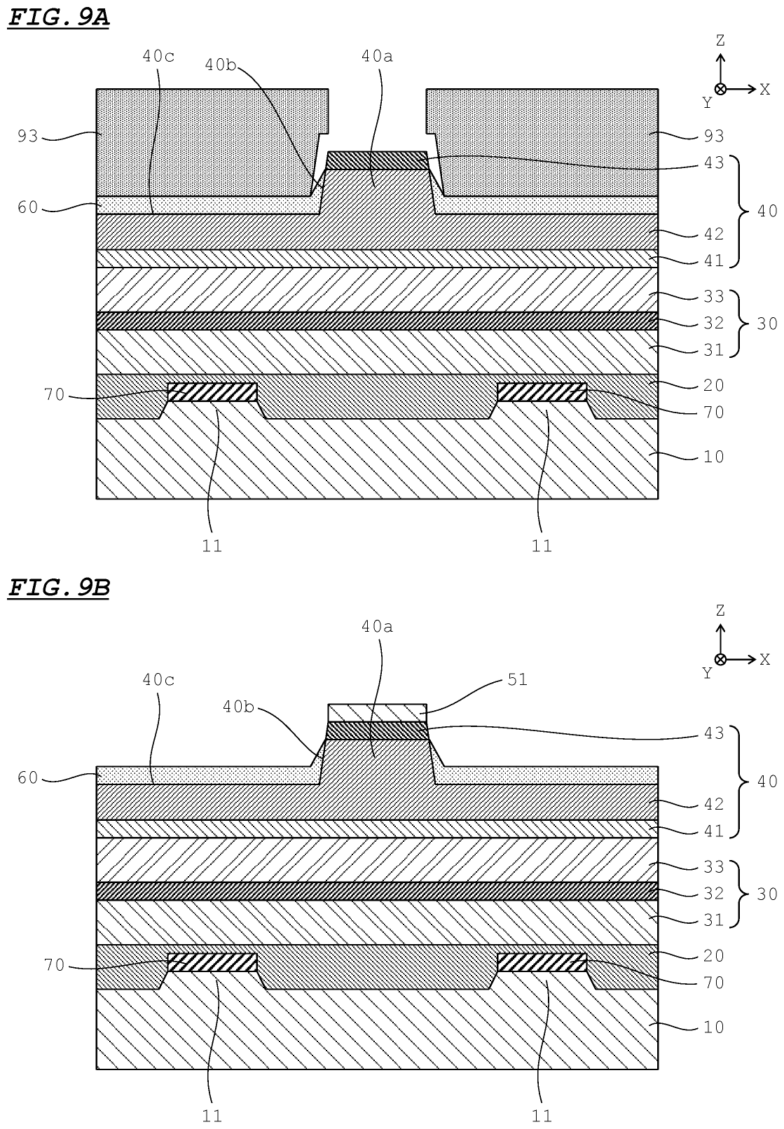

Next, a third protection film 93 composed of a photoresist is formed on the dielectric layer 60 shown in FIG. 8B. Subsequently, the third protection film 93 is selectively removed such that the third protection film 93 remains only on the flat part 40c. Subsequently, as shown in FIG. 9A, while using the third protection film 93 as a mask, only the dielectric layer 60 on the ridge part 40a is removed by wet etching using hydrofluoric acid, to expose the upper face of the p-side contact layer 43. Subsequently, the third protection film 93 is removed. For removal of the third protection film 93, an organic solvent such as acetone can be used.

Next, as shown in FIG. 9B, the p-side electrode 51 of Pd/Pt is formed only on the ridge part 40a, by using a vacuum evaporation method and a lift-off method. Specifically, the A-side electrode 51 is formed on the p-side contact layer 43 exposed from the dielectric layer 60. The film formation method for the p-side electrode 51 is not limited to the vacuum evaporation method, and a sputtering method, a pulsed laser film formation method, or the like may be used. The electrode material of the p-side electrode 51 only needs to be a material, such as a Ni/Au-based material or a Pt-based material, that comes into ohmic contact with the second semiconductor layer 40 (the p-side contact layer 43).

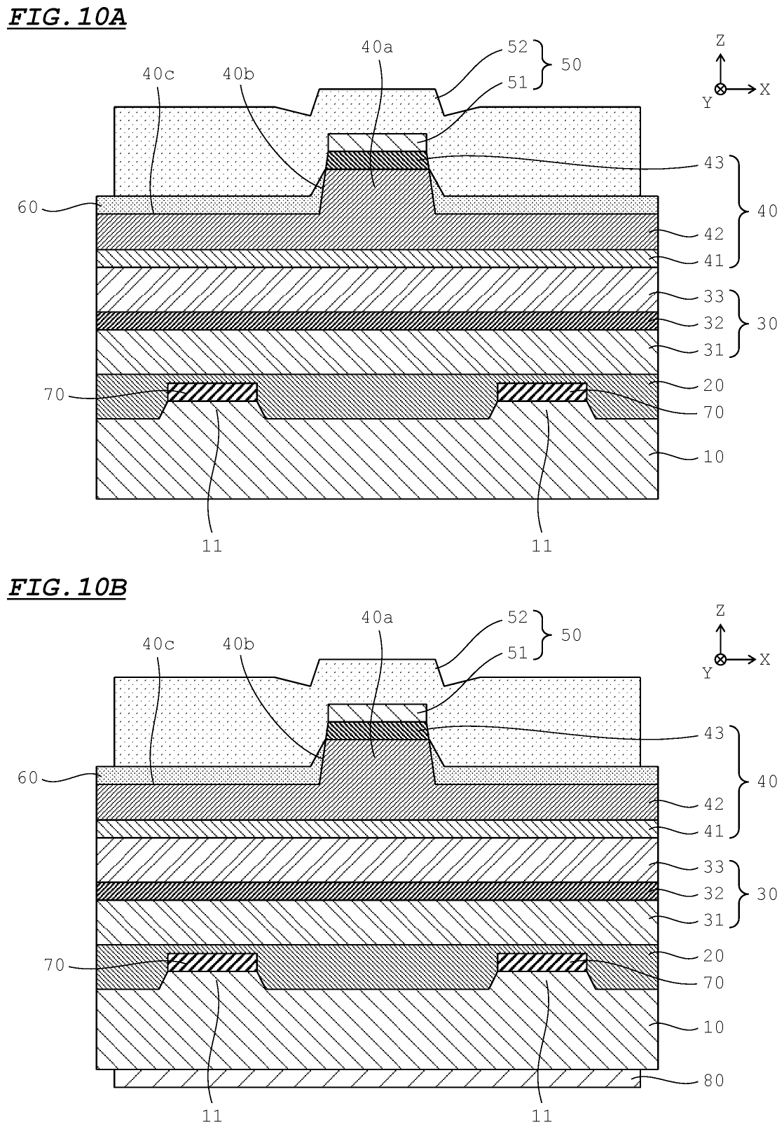

Next, as shown in FIG. 10A, the pad electrode 52 is formed so as to cover the p-side electrode 51 and the dielectric layer 60. Specifically, a negative-type resist is patterned by a photolithography method or the like, in a portion other than the portion where the pad electrode 52 is to be formed, and the pad electrode 52 of Ti/Pt/Au is formed on the entire face above the substrate 10 by a vacuum evaporation method or the like. Then, the electrode in an unnecessary portion is removed by using a lift-off method. Accordingly, the pad electrode 52 having a predetermined shape can be formed on the p-side electrode 51 and the dielectric layer 60. In this manner, the electrode member 50 composed of the p-side electrode 51 and the pad electrode 52 is formed. Subsequently, the lower face of the substrate 10 is polished with a diamond slurry, to thin the substrate 10 so as to have a thickness of about 100 μm.

Next, as shown in FIG. 10B, the n-side electrode 80 is formed at the lower face (the main face on the back side of the main face where the first semiconductor layer 20 and the like are disposed) of the substrate 10. Specifically, the n-side electrode 80 of Ti/Pt/Au is formed at the lower face of the substrate 10 by a vacuum evaporation method or the like, and patterning is performed by using a photolithography method and an etching method, whereby the n-side electrode 80 having a predetermined shape is formed.

Next, the semiconductor laser element having been subjected to the production steps up to FIG. 10B is cleaved (primary cleavage) along the m plane such that the length in the m-axis direction is, for example, 2000 μm. Subsequently, using, for example, an electron cyclotron resonance (ECR) sputtering method, a front coat film is formed for a cleavage plane from which laser light is emitted, thereby forming the end face 1a, and a rear coat film is formed for a cleavage plane on the opposite side, thereby forming the end face 1b. The reflectance of the end face 1a, 1b is set through adjustment of the material, configuration, film thickness, etc., of the coat film. Here, in order to obtain high-efficiency laser characteristics, the reflectance of the end face 1a on the front side is set to 5%, and the reflectance of the end face 1b on the rear side is set to 95%. Preferably, the reflectance of the end face 1a is set to about 0.1% to 18%, and the reflectance of the end face 1b is set to not less than 90%.

Subsequently, the semiconductor light-emitting element having been subjected to primary cleavage is cleaved (secondary cleavage) such that the pitch in terms of the length in the X-axis direction is 400 μm, for example. Accordingly, the semiconductor laser element 1 shown in FIGS. 1 and 2 is completed.

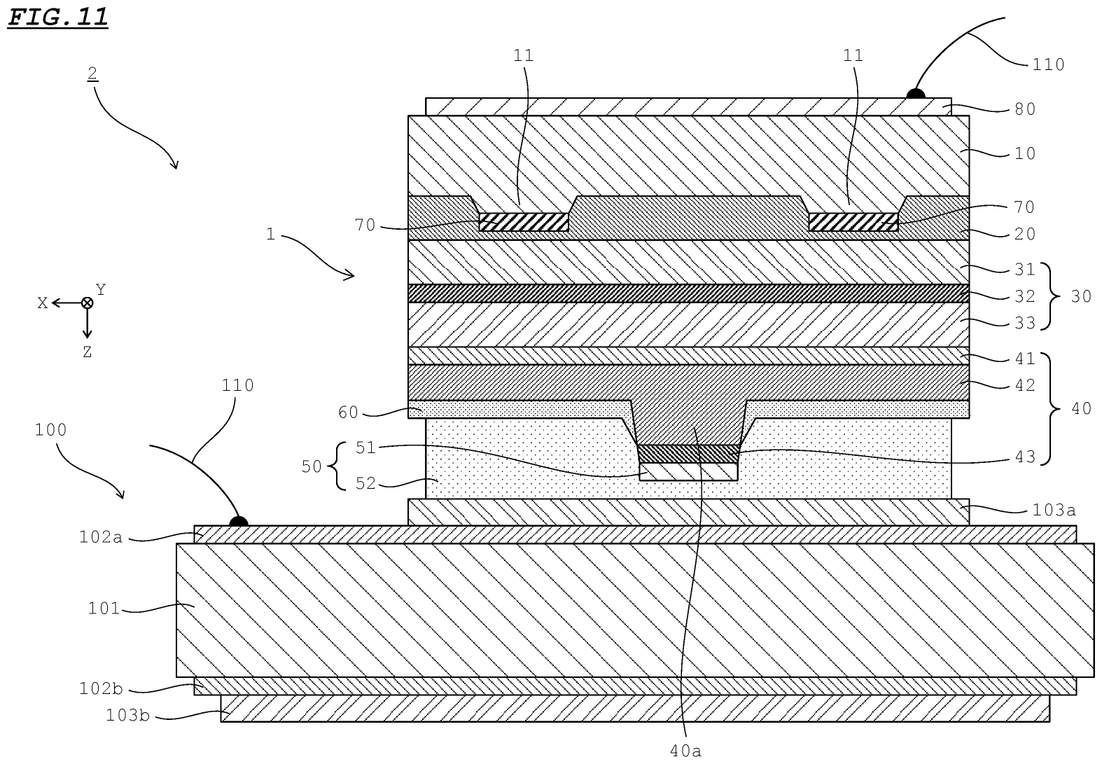

FIG. 11 is a cross-sectional view schematically showing a configuration of a semiconductor laser device 2 having the semiconductor laser element 1 mounted thereon. In FIG. 11, a state where the semiconductor laser element 1 in FIG. 2 is placed upside down (a state where the Z-axis positive direction is the downward direction) is shown.

The semiconductor laser device 2 includes the semiconductor laser element 1 and a submount 100, and is used in processing of a product, for example. The submount 100 has a base 101, a first electrode 102a, a second electrode 102b, a first adhesion layer 103a, and a second adhesion layer 103b.

The base 101 is disposed on the Z-axis positive side of the substrate 10 of the semiconductor laser element 1, and functions as a heat sink. The material of the base 101 is not limited in particular, and the base 101 may be formed of a material that has a thermal conductivity equivalent to or greater than that of the semiconductor laser element 1, such as: a ceramic such as aluminum nitride (AlN) or silicon carbide (SiC); diamond (C) formed by CVD; a metal elemental substance such as Cu or Al; or an alloy such as CuW.

The first electrode 102a is disposed at the face on the Z-axis negative side of the base 101, and the second electrode 102b is disposed at the face on the Z-axis positive side of the base 101. The first electrode 102a and the second electrode 102b are each a lamination film composed of three metal films of a 0.1 μm-thick Ti film, a 0.2 μm-thick Pt film, and a 0.2 μm-thick Au film, for example.

The first adhesion layer 103a is disposed at the face on the Z-axis negative side of the first electrode 102a, and the second adhesion layer 103b is disposed at the face on the Z-axis positive side of the second electrode 102b. The first adhesion layer 103a and the second adhesion layer 103b are each a eutectic solder composed of a gold-tin alloy containing Au and Sn at contents of 70% and 30%, respectively, for example.

The semiconductor laser element 1 is mounted on the submount 100 such that the p side (the electrode member 50 side) of the semiconductor laser element 1 is connected to the submount 100. That is, the mounting form in FIG. 11 is a junction-down mounting, and the pad electrode 52 of the semiconductor laser element 1 is connected to the first adhesion layer 103a of the submount 100.

A wire 110 is connected by wire bonding to each of the n-side electrode 80 of the semiconductor laser element 1 and the first electrode 102a of the submount 100. Accordingly, a voltage can be applied to the semiconductor laser element 1 through the wires 110.

The semiconductor laser device 2 shown in FIG. 11 is mounted in a form (junction-down mounting) in which the p side (the electrode member 50 side) of the semiconductor laser element 1 is connected to the submount 100. However, not limited thereto, a form (junction-up mounting) in which the n-side electrode 80 of the semiconductor laser element 1 is connected to the submount 100 may be adopted. Further, for the semiconductor laser device 2, a form in which separate submounts are respectively connected to the electrode member 50 and the n-side electrode 80 may be adopted.

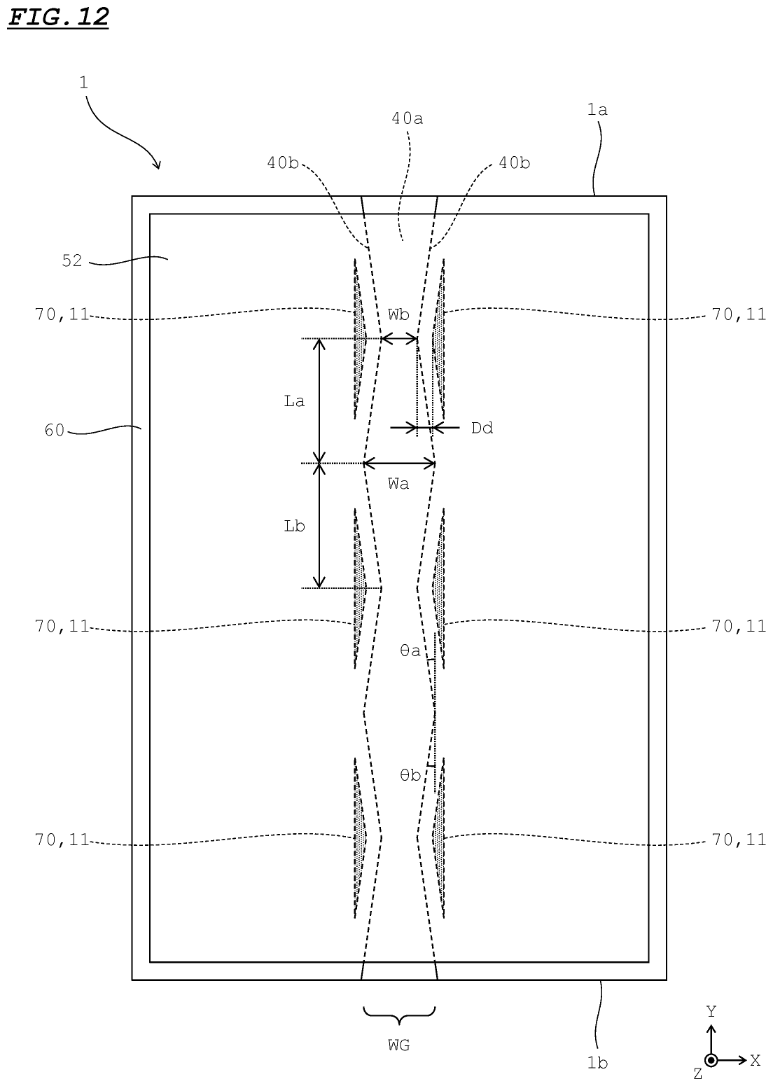

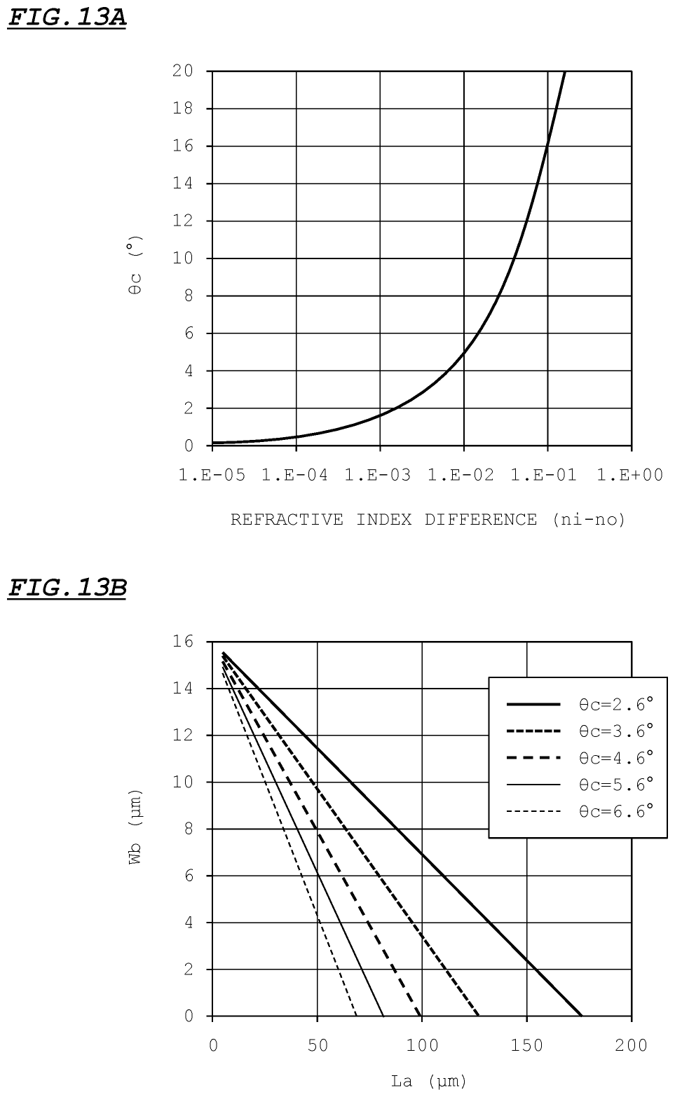

Next, with reference to FIG. 12 to FIG. 13B, the shape of the side face 40b of the ridge part 40a will be described.

FIG. 12 is a schematic diagram showing sizes of the side face 40b of the ridge part 40a. Similar to FIG. 1, FIG. 12 is a top view schematically showing a configuration of the semiconductor laser element 1.

The width (hereinafter, simply referred to as “width”) in the X-axis direction of the ridge part 40a continuously and cyclically changes in accordance with the position in the Y-axis direction (the waveguiding direction), and a position having a large width and a portion having a small width are alternately disposed in the Y-axis direction.

Here, the local maximum value of the width of the ridge part 40a is defined as Wa, and the local minimum value of the width of the ridge part 40a is defined as Wb. The distance in the Y-axis direction from the position where the width of the ridge part 40a has the local maximum value Wa to the position adjacent thereto on the Y-axis positive side out of the positions where the width of the ridge part 40a has the local minimum value Wb, is defined as La. The distance in the Y-axis direction from the position where the width of the ridge part 40a has the local maximum value Wa to the position adjacent thereto on the Y-axis negative side out of the positions where the width of the ridge part 40a has the local minimum value Wb, is defined as Lb. The side face 40b extending from the position where the width of the ridge part 40a has the local maximum value Wa to the position where the width of the ridge part 40a has the local minimum value Wb has a linear shape in a top view. The angle between the Y-axis direction and the side face 40b extending from the position where the width of the ridge part 40a has the local maximum value Wa toward the Y-axis positive side is defined as θa. The angle between the Y-axis direction and the side face 40b extending from the position where the width of the ridge part 40a has the local maximum value Wa toward the Y-axis negative side is defined as θb.

The relationship between θa, θb, Wa, Wb, La, and Lb is represented by formulae (1), (2) below.

θa=arctan{(Wa−Wb)/(2×La)} (1)

θb=arctan{(Wa−Wb)/(2×Lb)} (2)

In the present embodiment, the angles θa, θb are each set to be larger than a limit angle θc. The limit angle θc is the maximum value of the angle at which laser light is totally reflected at the side face 40b of the ridge part 40a. That is, the angle θa, θb is set so as to satisfy formula (3) below.

θa>θc and θb>θc (3)

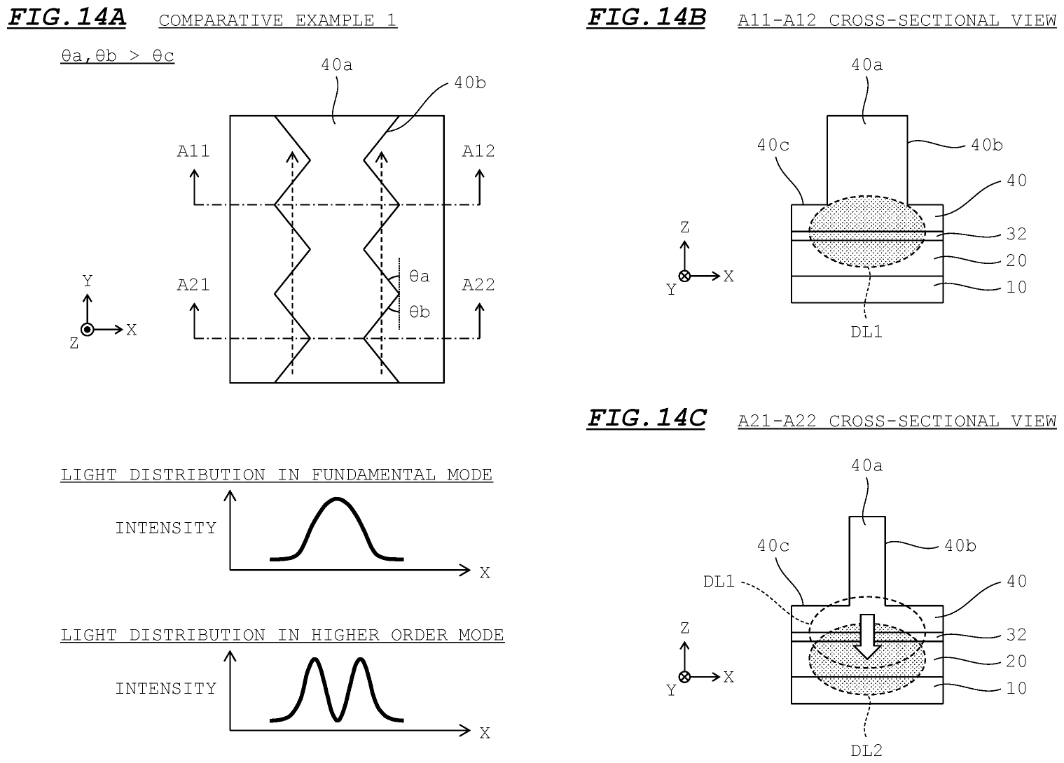

When the angle θa, θb is set to be larger than the limit angle θc, light in the higher order mode can be reduced and the proportion of light in the fundamental mode can be increased, as described later with reference to FIG. 14A.

Next, a setting example of Wa, Wb, La, Lb, θa, and θb will be described.

For example, the width of the ridge part 40a is not less than 1 μm and not greater than 100 μm. In order to cause the semiconductor laser element 1 to operate at a high light output (e.g., watt class), the local maximum value Wa of the width of the ridge part 40a may be set to not less than 10 μm and not greater than 50 μm. The smaller the local minimum value Wb of the width of the ridge part 40a is, the more the higher order mode component can be reduced. However, when the local minimum value Wb is too small, the fundamental mode component (fundamental transverse mode component) is also lost and reduced. Meanwhile, when the local minimum value Wb of the width of the ridge part 40a is made large, the higher order mode component reduction effect is reduced. In order to efficiently suppress the higher order mode component while maintaining the intensity according to the fundamental mode, the local minimum value Wb of the width of the ridge part 40a may be set to about not less than ¼ and not greater than ¾ of the local maximum value Wa of the width.

When the distance La, Lb is decreased, the angle θa, θb is increased, and thus, formula (3) above is easily satisfied. Meanwhile, when the distance La, Lb is increased too much, the number of the portions where the width of the ridge part 40a is small is reduced in the range of the length in the Y-axis direction of the semiconductor laser element 1. Thus, the higher order mode suppression effect is reduced. In the present embodiment, Wa=16 μm, Wb=10 μm, and La=Lb=30 μm are set. At this time, θa=θb=5.7° is realized.

As long as the conditions of formulae (1), (2) above are satisfied, La≠Lb may be allowed. In a case of La≠Lb, while light goes to and fro in the Y-axis direction in the resonator, loss on the higher order mode can be made different between the forward path and the backward path. For example, in a case of La>Lb, loss on the higher order mode when light advances from the end face 1b to the end face 1a can be increased.

As described above, the low refractive index part 70 composed of a silicon oxide film is disposed on the outer side of the side face 40b of the ridge part 40a. Here, when the ridge part 40a and the low refractive index part 70 are separated from each other by a certain distance Dd in the width direction (the X-axis direction) of the ridge part 40a, formula (4) below needs to be satisfied in order for the low refractive index part 70 to give an effect on light propagating on the outer side of the ridge part 40a.

Wb+2×Dd<Wa (4)

Here, when the distance Dd is too small, the proportion under influence of the low refractive index part 70 in the fundamental mode component increases, whereby the loss in the fundamental mode increases. Therefore, the distance Dd needs to be large to some extent. As a result of studies conducted by the inventors, it was found that, when the distance Dd is not less than 1 μm, loss in the fundamental mode component can be suppressed. In the X-axis direction, the end, on the opposite side to the ridge part 40a, of the low refractive index part 70 may be at the same position as or on the outer side of that of the side face 40b of the ridge part 40a where the width has the local maximum value Wa. In the present embodiment, Dd=2 μm is set, and in the X-axis direction, the end, on the opposite side to the ridge part 40a, of the low refractive index part 70 is at the same position as that of the side face 40b of the ridge part 40a where the width has the local maximum value Wa.

Next, how to obtain the limit angle θc will be described.

In the method below, using an equivalent refractive index method, a three-dimensional structure of the ridge part 40a is approximated by a two-dimensional slab waveguide structure. At the center position in the X-axis direction of the ridge part 40a, an equivalent refractive index ni at this position is calculated by using the thickness and the refractive index of each layer. Similarly, at the center position in the X-axis direction of the low refractive index part 70, an equivalent refractive index no at this position is calculated by using the thickness and the refractive index of each layer. The equivalent refractive index ni is the effective refractive index on the inner side of the ridge part 40a, and the equivalent refractive index no is the effective refractive index on the outer side of the ridge part 40a. In the present embodiment, due to formation of the ridge part 40a, ni>no is always satisfied.

Next, using Snell's law, the maximum value of the angle when a total reflection condition is satisfied, i.e., the limit angle θc, is calculated. The limit angle θc is calculated by formula (5) below.

θc=90°−arcsin(no/ni) (5)

For example, when ni=2.535 and no=2.527, θc=4.6° is calculated based on formula (5) above. Using θc calculated in this manner, Wa, Wb, La, and Lb are set so as to satisfy formulae (1) to (3) above.

Next, an example of the procedure of actually determining each set value will be described.

FIG. 13A is a graph showing a relationship between a refractive index difference (ni−no) between the inside and the outside of the ridge part 40a, and the limit angle θc. In FIG. 13A, the horizontal axis represents the refractive index difference (ni−no) and the vertical axis represents the limit angle θc. The graph in FIG. 13A is made based on formula (5) above.

As described above, when the equivalent refractive index ni, no is calculated by using the thickness and the refractive index of each layer, the limit angle θc can be calculated based on formula (5) above or the graph in FIG. 13A.

FIG. 13B is a graph showing a relationship between the distance La and the local minimum value Wb that satisfy the formula (3) above, when the local maximum value Wa is fixedly set to 16 μm, and the limit angle θc is 2.6°, 3.6°, 4.6°, 5.6°, or 6.6°. In FIG. 13B, the horizontal axis represents the distance La, and the vertical axis represents the local minimum value Wb.

In a region below each straight line in FIG. 13B, the condition of formula (3) above is satisfied. Therefore, when the local minimum value Wb and the distance La are set so as to be included in the region below the straight line corresponding to the limit angle θc, the angle θa can be set to be larger than the limit angle θc. With respect to the distance Lb as well, when the local minimum value Wb and the distance Lb are set so as to be included in the region below the straight line corresponding to the limit angle θc, the angle θb can be set to be larger than the limit angle θc.

In this manner, the limit angle θc is calculated based on the equivalent refractive indexes ni and no on the inside and the outside of the ridge part 40a, and the local maximum value Wa, the local minimum value Wb, and the distance La, Lb can be set based on the calculated θc. Accordingly, formula (3) above is satisfied, and thus, light in the higher order mode can be reduced.

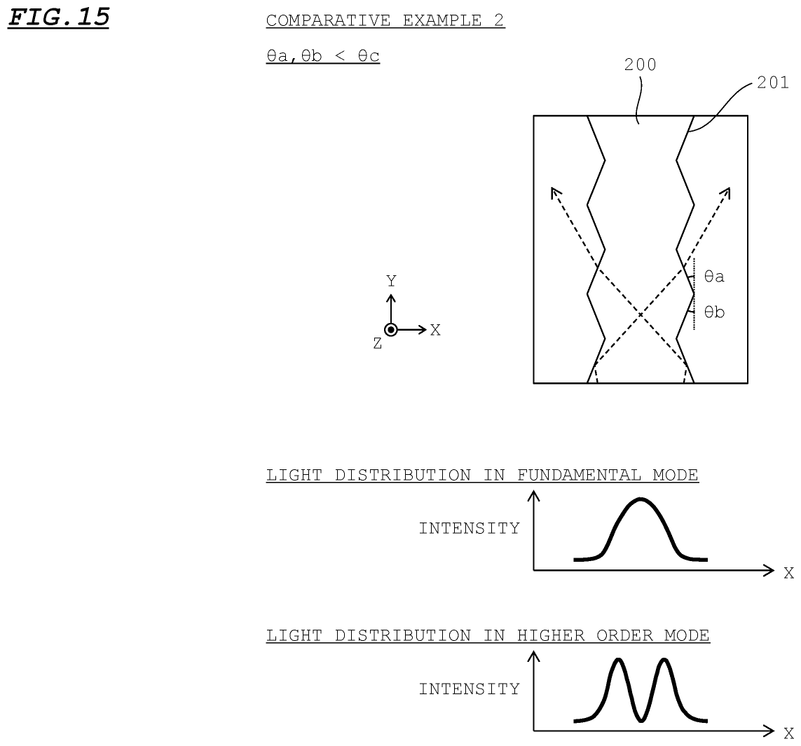

Next, with reference to Comparative Example 1 shown in FIGS. 14A to 14C and Comparative Example 2 shown in FIG. 15, advantages and disadvantages of Comparative Examples 1 and 2 will be described.

FIG. 14A is a top view schematically showing a configuration of a semiconductor laser element according to Comparative Example 1. In a lower part of FIG. 14A, graphs schematically showing examples of light distribution in the fundamental mode and the higher order mode in the X-axis direction are included.

In Comparative Example 1, when compared with the embodiment above, the low refractive index part 70 and the projection 11 are omitted. In the semiconductor laser element of Comparative Example 1, during laser oscillation, light propagates in the Y-axis direction in the ridge part 40a. At this time, the total reflection condition is not satisfied on the inside and the outside of the ridge part 40a (since the formula (3) above is satisfied), and thus, light generally propagates in the Y-axis direction even if there is a portion where the width of the ridge part 40a is small. In FIG. 14A, how light propagates is indicated by broken line arrows. In a portion where the width of the ridge part 40a is small, light advances slightly on the inner side under the influence of the refractive index difference between the inside and the outside of the ridge part 40a. However, since the total reflection condition is not satisfied, most of the light advances in the Y-axis direction while passing through the outside of the ridge part 40a.

Here, light propagating at the ridge part 40a includes

light in the fundamental mode and the higher order mode shown in the graphs in the lower part of FIG. 14A. As in Comparative Example 1, when formula (3) above is satisfied, the light component in the higher order mode is lost due to the side face 40b of the ridge part 40a, and the proportion of the fundamental mode can be increased.

FIGS. 14B and 14C are cross-sectional views, respectively, schematically showing configurations of the semiconductor laser of Comparative Example 1 shown in FIG. 14A at an A11-A12 cross section and an A21-A22 cross section viewed in the Y-axis positive direction. In FIGS. 14B and 14C, for convenience, only the substrate 10, the first semiconductor layer 20, the active layer 32, and the second semiconductor layer 40 are shown.

As shown in FIG. 14B, the semiconductor laser element is configured such that, at a position where the width of the ridge part 40a is large, light propagating in the ridge part 40a is confined in the vicinity of the active layer 32, as indicated by a light distribution DL1 in the fundamental mode. In this case, light propagating in the ridge part 40a is less likely to overlap the substrate 10.

However, as shown in FIG. 14C, at a position where the width of the ridge part 40a is small, light propagating on the outer side of the ridge part 40a is pushed down to the substrate 10 side as indicated by a light distribution DL2 in the fundamental mode, since the thickness of the p-side clad layer 42 on the outer side of the ridge part 40a is small. Therefore, between the active layer 32 and the first semiconductor layer 20, and between the first semiconductor layer 20 and the substrate 10, excitation in a higher order mode in the vertical direction referred to as a substrate mode is caused. When this substrate mode is caused, ripples are caused in the vertical FFP. Such ripples increase in particular due to a higher order mode that has a peak of light intensity on the outer side of the ridge part 40a.

FIG. 15 is a top view schematically showing a configuration of a semiconductor laser element according to Comparative Example 2. In FIG. 15, graphs schematically showing examples of light distribution in the fundamental mode and the higher order mode in the X-axis direction are included.

In Comparative Example 2, when compared with the embodiment above, the low refractive index part 70 and the projection 11 are omitted, and, instead of the ridge part 40a, a ridge part 200 is formed in an upper portion of the second semiconductor layer 40. In Comparative Example 2, the total reflection condition is satisfied on the inside and the outside of the ridge part 200. That is, in Comparative Example 2, instead of formula (3) above, θa<θc and θb<θc are satisfied.

In Comparative Example 2, since formula (3) above is not satisfied, light in the higher order mode cannot be reduced in the form as in Comparative Example 1. However, in Comparative Example 2, ripples in the vertical FFP caused in the case of Comparative Example 1 can be suppressed.

In the semiconductor laser element of Comparative Example 2, the refractive index difference between the inside and the outside of the ridge part 200 satisfies the total reflection condition. Thus, as indicated by broken line arrows in FIG. 15, light in the ridge part 200 is reflected at one side face 201 of the ridge part 200, and the reflected light passes through the other side face 201 of the ridge part 200, to be radiated to the outside of the ridge part 200. That is, light emitted as laser light to the outside of the semiconductor laser element does not propagate on the outer side of the ridge part 200. Thus, the substrate mode caused in Comparative Example 1 is suppressed in the structure of the ridge part 200 of Comparative Example 2. Therefore, according to the semiconductor laser element of Comparative Example 2, ripples in the vertical FFP can be suppressed.

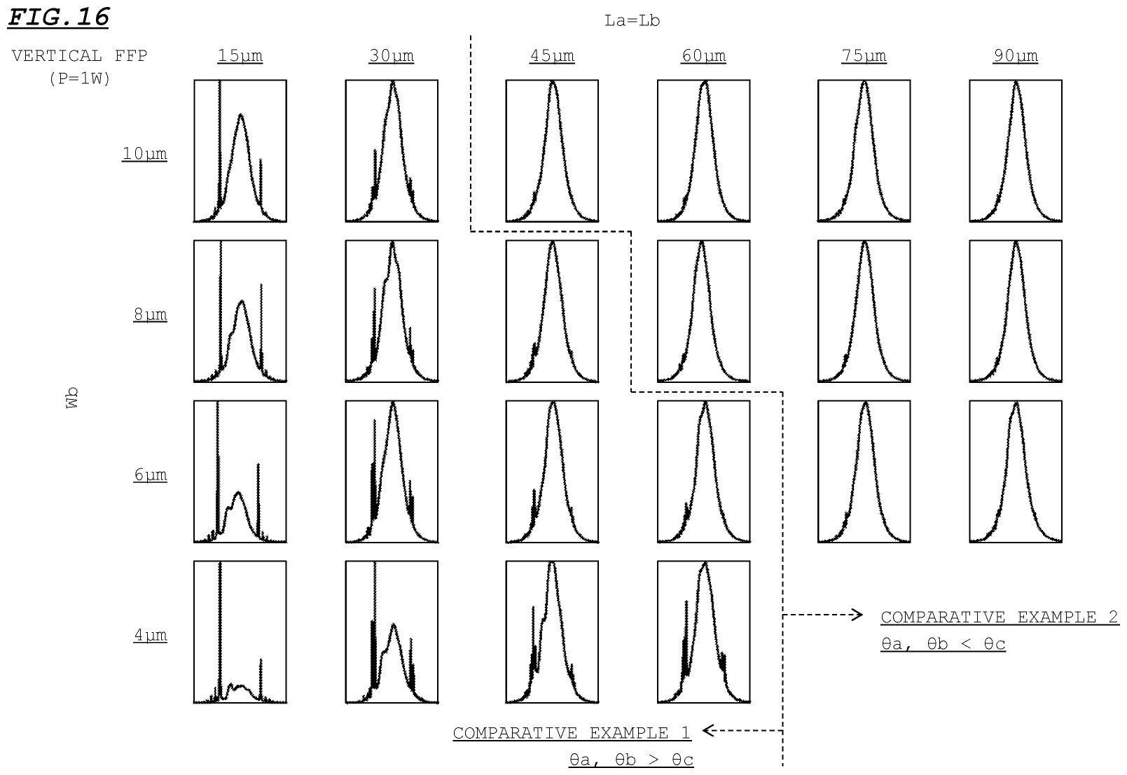

FIG. 16 is graphs showing a result of an experiment on vertical FFP obtained when the structures of ridge parts of the semiconductor laser elements according to Comparative Examples 1 and 2 are changed.

With reference to FIG. 12 showing sizes of components, in the present experiment, La=Lb and Wa=16 μm were fixedly set, and the distance La was changed in a range of 15 μm to 90 μm, at an interval of 15 μm. The local minimum value Wb of the width was changed in a range of 4 μm to 10 μm, at an interval of 2 μm. In the present experiment, similar to Comparative Examples 1 and 2, the low refractive index part 70 and the projection 11 were not provided.

FIG. 16 shows the vertical FFP when the light output was 1 W, in the semiconductor laser elements having these respective structures. In each graph in FIG. 16, the vertical axis represents light intensity normalized with the maximum value, and the horizontal axis represents normalized angle. In FIG. 16, graphs of the vertical FFP based on the semiconductor laser element of Comparative Example 1 satisfying the relationship of formula (3) above, and graphs of the vertical FFP based on the semiconductor laser element of Comparative Example 2 not satisfying the relationship of formula (3) above are demarcated by a broken line.

As shown in the graphs on the left side of the broken line, it is understood that, in the semiconductor laser element (Comparative Example 1) satisfying θa>θc and θb>θc, ripples (disturbance) were caused in the vertical FFP. Meanwhile, as shown in the graphs on the right side of the broken line, it is understood that, in the semiconductor laser element (Comparative Example 2) satisfying θa<θc and θb<θc, ripples are not caused in the vertical FFP. In addition, it is understood that the smaller the local minimum value Wb of the width is, the greater the intensity of ripples becomes. This is because the smaller the local minimum value Wb of the width is, the greater the proportion of light passing through the outer side of the ridge part becomes. In the graphs on the left side of the broken line, it is understood that ripples become smaller in a structure closer to the structure satisfying the relationship of θa<θc and θb<θc. This is because the proportion of light satisfying the condition of θa<θc and θb<θc, i.e., the total reflection condition, increases.

As described above, in the semiconductor laser element of Comparative Example 1 satisfying the relationship of formula (3) above, ripples are caused in the vertical FFP. Meanwhile, in the semiconductor laser element of Comparative Example 2 not satisfying the relationship of formula (3) above, ripples are less likely to be caused in the vertical FFP, but it is difficult to reduce light in the higher order mode, as described with reference to FIG. 15. In contrast to this, the semiconductor laser element 1 according to the present embodiment satisfies the relationship of formula (3) above, and includes the low refractive index part 70 for suppressing ripples in the vertical FFP.

With reference to FIGS. 17A to 17C, effects of the low refractive index part 70 of the semiconductor laser element 1 according to the present embodiment will be described.

FIG. 17A is a top view schematically showing a configuration of the semiconductor laser element 1 according to the embodiment. In a lower part of FIG. 17A, graphs schematically showing examples of light distribution in the fundamental mode and the higher order mode in the X-axis direction are included.

In the embodiment, similar to Comparative Example 1 above, light generally propagates in the Y-axis direction as indicated by broken line arrows. At this time, light propagating at the ridge part 40a includes light in the fundamental mode and the higher order mode shown in the graphs in the lower part of FIG. 17A. In the embodiment, formula (3) above is satisfied as in Comparative Example 1. Thus, the light component in the higher order mode is lost due to the side face 40b of the ridge part 40a, and the proportion of the fundamental mode can be increased.

FIGS. 17B and 17C are cross-sectional views, respectively, schematically showing configurations of the semiconductor laser element 1 of the embodiment shown in FIG. 17A at an A31-A32 cross section and an A41-A42 cross section viewed in the Y-axis positive direction. In FIGS. 17B and 17C, for convenience, only the substrate 10, the first semiconductor layer 20, the active layer 32, the second semiconductor layer 40, and the low refractive index part 70 are shown.

As shown in FIG. 17B, at a position where the width of the ridge part 40a is large, similar to Comparative Example 1, light propagating in the ridge part 40a is less likely to overlap the substrate 10 as indicated by a light distribution DL3 in the fundamental mode.

As shown in FIG. 17C, at a position where the width of the ridge part 40a is small, the low refractive index part 70 is formed on the outer side of the ridge part 40a, and light passing through the outer side of the ridge part 40a passes directly above the low refractive index part 70.

Here, the low refractive index part 70 is formed by a silicon oxide film as described above, and thus has a refractive index lower than that of the first semiconductor layer 20. Thus, when the low refractive index part 70 having a low refractive index is formed below (on the first semiconductor layer 20 side with respect to the active layer 32) in a light passage region, downward movement of light is restricted. That is, downward movement of light having propagated on the outer side of the ridge part 40a and reached directly above the low refractive index part 70 is suppressed. Therefore, as shown in FIG. 17C, a light distribution DL4 in the fundamental mode of laser light according to the present embodiment is at an upper position relative to the light distribution DL2 in the fundamental mode of laser light when the low refractive index part 70 is not provided (Comparative Example 1). Accordingly, light moving toward the substrate 10 can be reduced, and thus, the substrate mode can be reduced. Therefore, according to the semiconductor laser element 1 of the present embodiment, ripples in the vertical FFP can be suppressed.

### Effects of Embodiment

According to the embodiment, the following effects are achieved.

Since the angle θa, θb between the side face 40b of the ridge part 40a and the waveguiding direction (the Y-axis direction) is set to be larger than the limit angle θc, laser light in the higher order mode is cut, and the proportion of laser light in the fundamental mode is increased. The low refractive index part 70 is disposed between the active layer 32 of the light emission layer 30 and the projection 11 of the substrate 10, and on the outer side of the side face 40b at least where the width of the ridge part 40a is small. Accordingly, as described with reference to FIG. 17C, downward movement of the distribution position of laser light propagating at the ridge part 40a (the waveguide WG) is less likely to occur, and thus, ripples in the vertical FFP is suppressed. When the projection 11 is provided at the upper face of the substrate 10, a portion near the lower end of laser light in the fundamental mode propagating in the ridge part 40a can be suppressed from being radiated from the upper face of the substrate 10 where the projection 11 is not disposed. Accordingly, decrease in laser light in the fundamental mode can be suppressed. Thus, while ripples in the vertical FFP are suppressed, the proportion of the fundamental mode can be increased.

The low refractive index part 70 is formed in the first semiconductor layer 20. Accordingly, while the distribution position of laser light propagating at the ridge part 40a (the waveguide WG) is kept at the light emission layer 30, downward movement of the distribution position of laser light can be effectively suppressed.

In a top view, the low refractive index part 70 is disposed along the side face 40b, on the outer side of the side face 40b of the ridge part 40a. Specifically, the low refractive index part 70 is disposed in parallel so as to be separated by the distance Dd (see FIG. 12) in the width direction with respect to the side face 40b. Accordingly, with the minimum disposition of the low refractive index part 70, downward movement of the distribution position of laser light propagating at the ridge part 40a (the waveguide WG) can be effectively suppressed.

The defect density of the light emission layer 30 disposed directly above the low refractive index part 70 is higher than the defect density of the light emission layer 30 other than directly above the low refractive index part 70. In this case, by the interface formed at the light emission layer 30 directly above the low refractive index part 70, unnecessary laser light in the higher order mode distributed in the vicinity of the light emission layer 30 directly above the low refractive index part 70 can be absorbed, and the higher order mode component can be reduced.

As shown in FIG. 2, since the cross section of the low refractive index part 70 has a rectangular shape, the inner end and the outer end in the X-axis direction of the low refractive index part 70 become parallel to the Z-axis direction. Accordingly, in the vicinity of the position P1 at the inner end and in the vicinity of the position P2 at the outer end, an interface is caused at each layer. When an interface is caused at each layer at the position P1, P2, laser light in the higher order mode can be scattered, and thus, the higher order mode component can be reduced.

The angle θa, θb between the side face 40b of the ridge part 40a and the waveguiding direction (the Y-axis direction) is set to be larger than the limit angle θc. In this case, the limit angle θc is the maximum value of the angle at which laser light is totally reflected at the side face 40b. Then, with the side face 40b of the ridge part 40a, the higher order mode component propagating at the ridge part 40a can be reduced, and the proportion of the fundamental mode can be increased.

### MODIFICATIONS

Although the embodiment of the present invention has been described above, the present invention is not limited to the above embodiment, and various other modifications may be made.

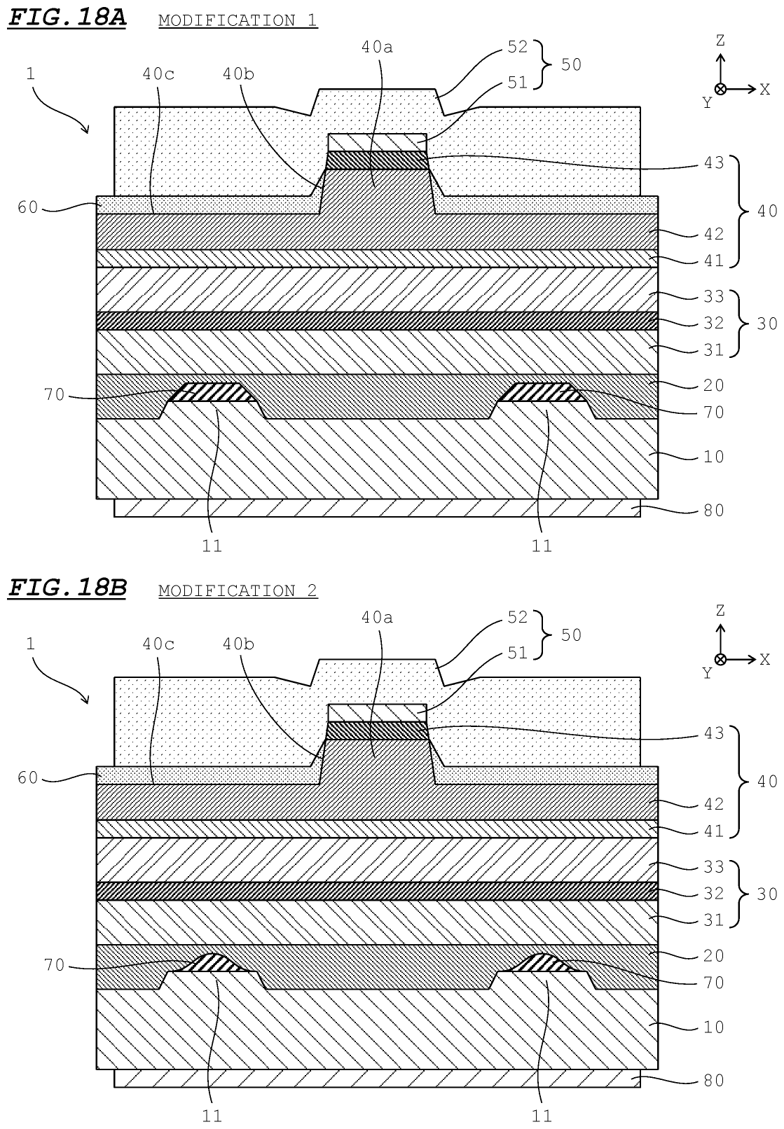

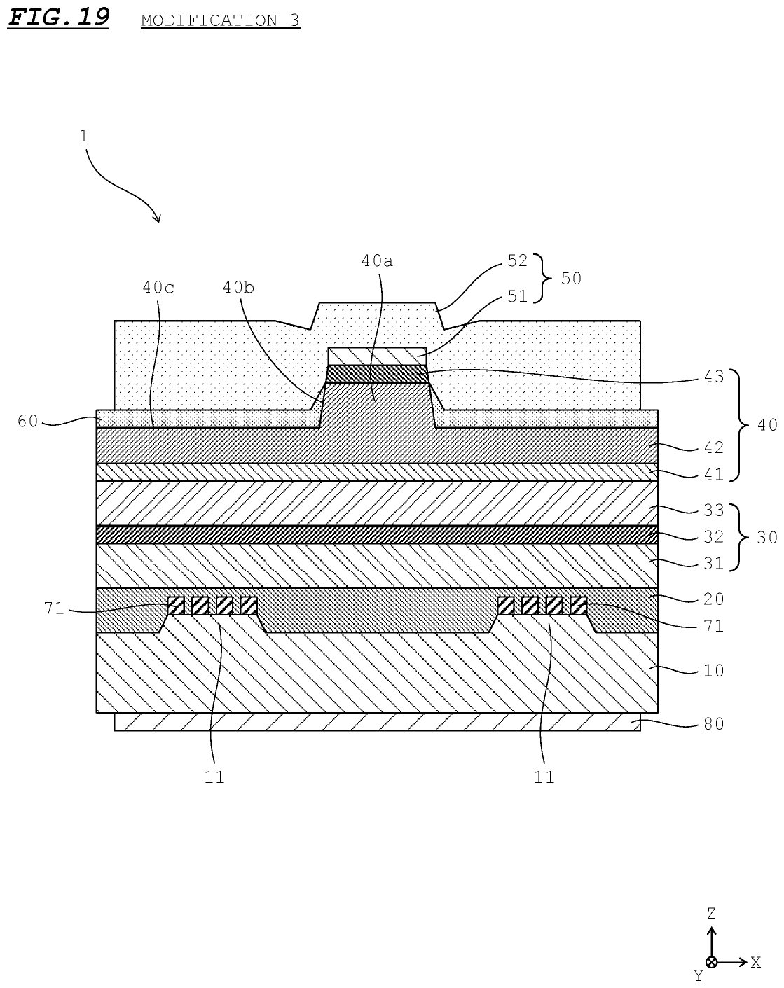

For example, in the embodiment above, in the A-A′ cross section, the shape of the low refractive index part 70 is a rectangular shape, but not limited thereto, may be another shape such as a circular shape or an elliptical shape. For example, the shape of the low refractive index part 70 may be a shape shown in Modification 1, 2 in FIG. 18A, 18B, and the low refractive index part 70 may be divided into a plurality of pieces as shown in Modification 3 in FIG. 19.

In Modification 1 shown in FIG. 18A and Modification 2 shown in FIG. 18B, the low refractive index part 70 is configured such that the width thereof in the X-axis direction becomes smaller upwardly. Specifically, in the Modification 1 in FIG. 18A, the shape of the low refractive index part 70 at the A-A′ cross section is a trapezoid shape. In Modification 2 in FIG. 18B, the shape of the low refractive index part 70 at the A-A′ cross section is a curved shape. When the width of the low refractive index part 70 becomes smaller upwardly, the low refractive index part 70 can be easily formed when compared with the rectangular shape shown in FIG. 2.

In Modification 3 shown in FIG. 19, when compared with the embodiment above, four low refractive index parts 71 arranged in the width direction (the X-axis direction) are formed instead of a single low refractive index part 70. As shown in FIG. 19, when a plurality of low refractive index parts 71 are disposed so as to be arranged in the width direction on the outer side of the ridge part 40a, embedding of the low refractive index part 70 is facilitated due to crystal growth of the first semiconductor layer 20 in the film formation step. In the case of FIG. 19, a plurality of interfaces are formed directly above the plurality of low refractive index parts 71. Thus, light in the higher order mode can be further reduced by these interfaces.

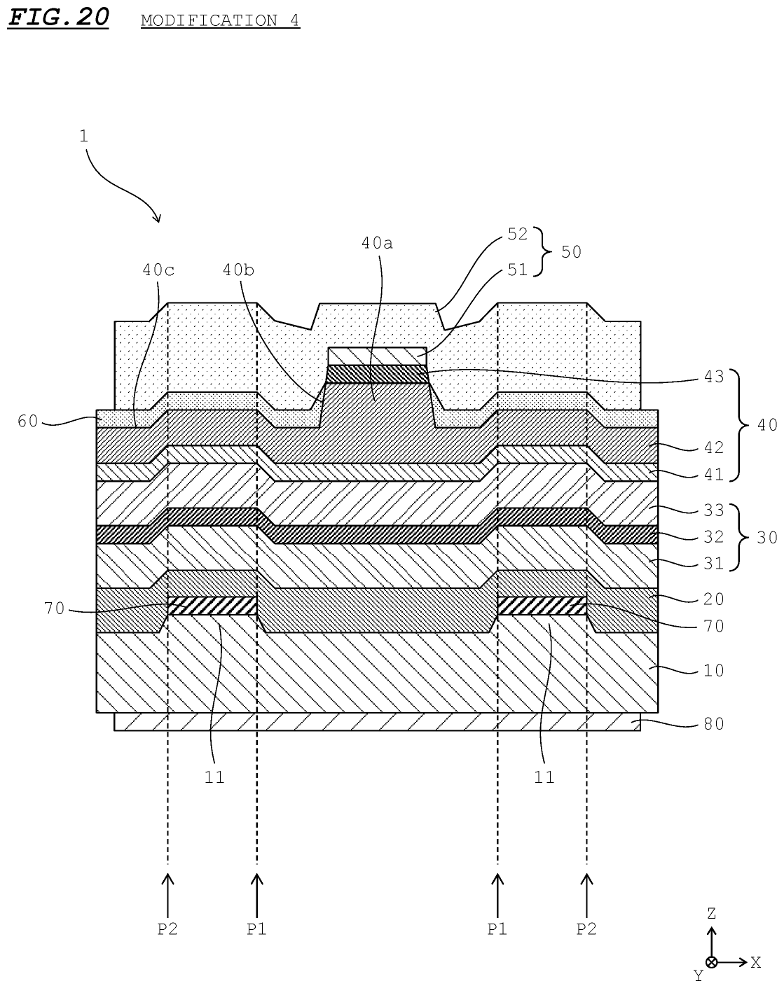

In the embodiment above, the respective layers laminated in the up-down direction are formed in parallel to an X-Y plane. However, as shown in Modification 4 in FIG. 20, the respective layers disposed directly above the low refractive index part 70 may be formed so as to be displaced upwardly with respect to the respective layers other than directly above the low refractive index part 70. In this case, as shown in FIG. 20, while the shape of the low refractive index part 70 is reflected, the respective layers above the low refractive index part 70 are formed, and at each layer above the low refractive index part, a step is caused in the vicinity of the position P1 at the inner end and in the vicinity of the position P2 at the outer end of the low refractive index part 70. Accordingly, in the width direction (the X-axis direction) of the low refractive index part 70, an interface is caused between (i.e., in the vicinity of the position P1, P2) the region directly above the low refractive index part 70, and the region other than directly above the low refractive index part 70. Therefore, with this interface, laser light in the higher order mode can be scattered, and thus, the higher order mode component can be reduced.

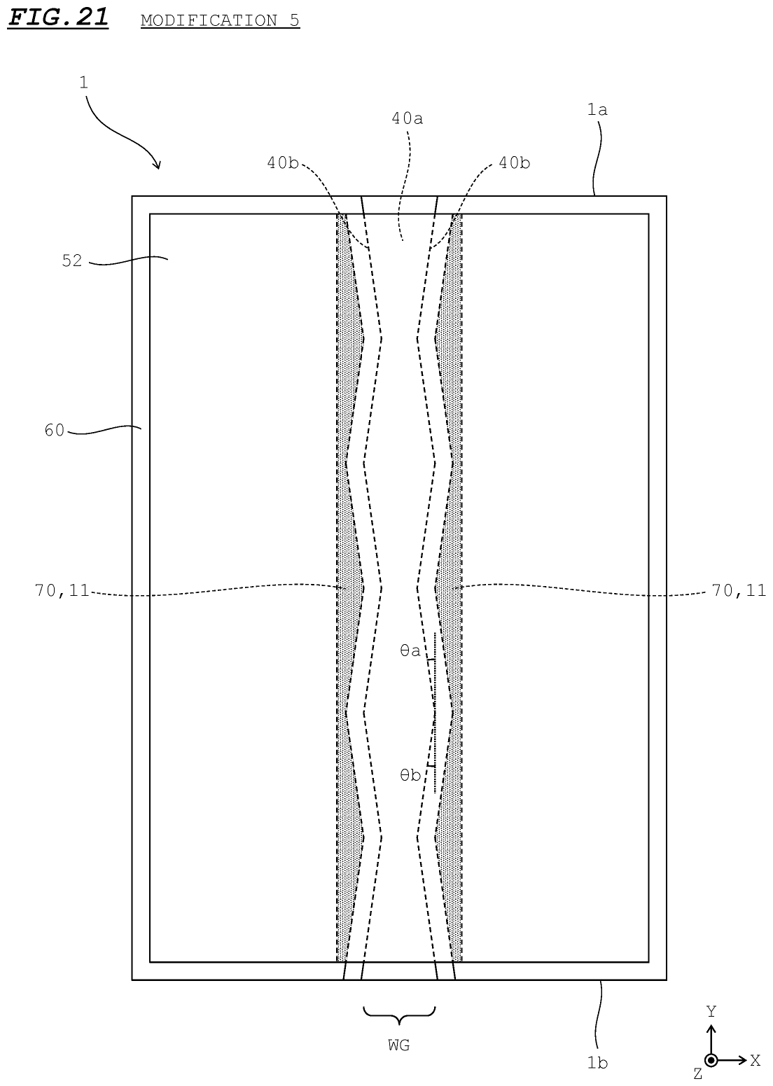

In the embodiment above, as shown in FIG. 1, the low refractive index part 70 is disposed on the outer side of the side face 40b where the width of the ridge part 40a has the local minimum value, and is not disposed on the outer side of the side face 40b where the width of the ridge part 40a has the local maximum value. However, not limited thereto, as shown in Modification 5 in FIG. 21, the low refractive index part 70 may be disposed over the entirety of the outer side of the side face 40b of the ridge part 40a.

In Modification 5 shown in FIG. 21, the low refractive index part 70 and the projection 11 are disposed with a certain interval from the side face 40b, on the outer side of the side face 40b. The inner ends of the low refractive index part 70 and the projection 11 are parallel to the side face 40b so as to correspond to cyclical change in the width direction of the side face 40b. The outer ends of the low refractive index part 70 and the projection 11 are parallel to the Y-axis direction. In Modification 5 shown in FIG. 21, the outer ends of the low refractive index part 70 and the projection 11 may also be parallel to the side face 40b so as to correspond to cyclical change in the width direction of the side face 40b.

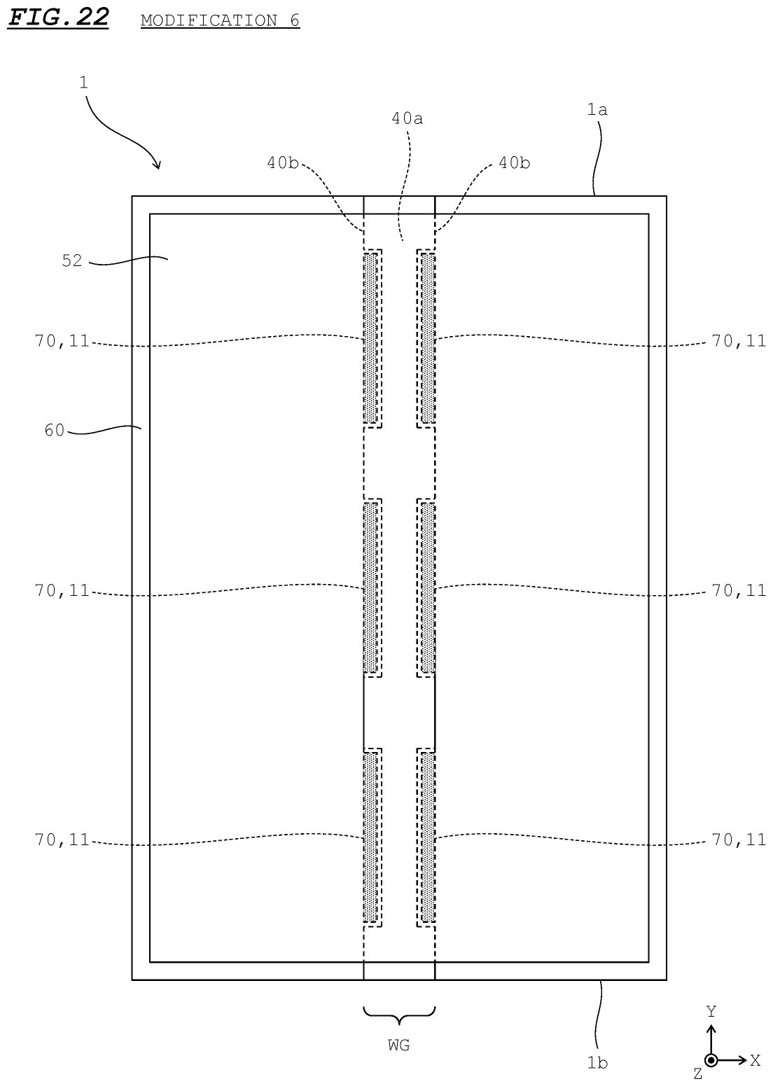

In the embodiment above, as shown in FIG. 1, in a top view, the side face 40b is inclined in a direction at the angle θa, θb with respect to the Y-axis direction, but need not necessarily extend in an oblique direction as shown in FIG. 1. For example, as shown in Modification 6 in FIG. 22, the side face 40b may be composed of a portion parallel to the Y-axis direction and a portion parallel to the X-axis direction.

In Modification 6 shown in FIG. 22, the portion of the side face 40b where the width of the ridge part 40a has the local minimum value and the portion of the side face 40b where the width of the ridge part 40a has the local maximum value each extend in the Y-axis direction, and the portion of the side face 40b where the width has the local minimum value and the portion of the side face 40b where the width has the local maximum value are connected by a portion of the side face 40b parallel to the X-axis direction. In this case as well, the width of the ridge part 40a cyclically changes in accordance with the position in the waveguiding direction (the Y-axis direction) of the ridge part 40a. The angle between the side face 40b of the ridge part 40a and the waveguiding direction (the Y-axis direction), i.e., the angle between the portion of the side face 40b parallel to the X-axis direction and the waveguiding direction (the Y-axis direction), is greater than the limit angle θc. The low refractive index part 70 and the projection 11 each have a rectangular shape in a top view, and are disposed on the outer side of the portion of the side face 40b where the width of the ridge part 40a has the local minimum value. Therefore, in Modification 6 as well, while ripples in the vertical FFP are suppressed, the proportion of the fundamental mode can be increased.

In the embodiment above, the side face 40b of the ridge part 40a has a linear shape in a top view. However, as long as the condition of formula (3) above is satisfied, the side face 40b may have a curved shape in a top view.

In the embodiment above, the low refractive index part 70 is formed in the first semiconductor layer 20, but not limited thereto, may be formed so as to extend across the n-side light guide layer 31 and the first semiconductor layer 20.

In the embodiment above, the low refractive index part 70 is implemented by a silicon oxide film (SiO₂), but not limited thereto, may be formed of a material having a refractive index lower than that of the first semiconductor layer 20. In this case as well, similar to the embodiment above, occurrence of ripples in the vertical FFP can be suppressed. Examples of the material of the low refractive index part 70 include SiN (refractive index: 2.07), Al₂O₃ (refractive index: 1.79), AlN (refractive index: 2.19), and ITO (refractive index: 2.12). When the low refractive index part 70 is formed of ITO, light in the higher order mode can be more suppressed.

In the embodiment above, the semiconductor laser element 1 and the semiconductor laser device 2 need not necessarily be used in processing of a product, and may be used in other usage.

In addition to the above, various modifications can be made as appropriate to the embodiment of the present invention, without departing from the scope of the technological idea defined by the claims.

What is claimed is:

1. A semiconductor laser element comprising:
a substrate having a projection at an upper face thereof;
a first semiconductor layer disposed above the substrate;
a light emission layer disposed above the first semiconductor layer;
a second semiconductor layer disposed above the light emission layer; and
a low refractive index part having a refractive index lower than that of the first semiconductor layer, wherein
the second semiconductor layer has a ridge part for guiding laser light generated in the light emission layer,
a width of the ridge part cyclically changes in accordance with a position in a waveguiding direction of the ridge part,
an angle between a side face of the ridge part and the waveguiding direction is larger than a limit angle defined by an effective refractive index on each of an inner side of the ridge part and an outer side of the ridge part, and
the low refractive index part is disposed between an active layer of the light emission layer and the projection of the substrate, and on the outer side of the side face at least where the width of the ridge part is small.

2. The semiconductor laser element according to claim 1, wherein
the low refractive index part is formed in the first semiconductor layer.

3. The semiconductor laser element according to claim 1, wherein
in a top view, the low refractive index part is disposed along the side face, on the outer side of the side face of the ridge part.

4. The semiconductor laser element according to claim 1, wherein
a defect density of the light emission layer disposed directly above the low refractive index part is higher than a defect density of the light emission layer other than directly above the low refractive index part.

5. The semiconductor laser element according to claim 1, wherein
the low refractive index part is configured such that a width thereof becomes smaller upwardly.

6. The semiconductor laser element according to claim 1, wherein
the light emission layer disposed directly above the low refractive index part is formed so as to be displaced upwardly with respect to the light emission layer other than directly above the low refractive index part.

7. The semiconductor laser element according to claim 1, wherein
the low refractive index part is implemented by a silicon oxide film.

8. The semiconductor laser element according to claim 1, wherein
the limit angle is a maximum value of an angle at which the laser light is totally reflected at the side face.
